(19) United States
(12) Patent Application Publication
(10) Pub. No.: US 2026/0081399 A1
(43) Pub. Date: Mar. 19, 2026

(54) SPECTRAL LINEWIDTH ADJUSTING METHOD AND ELECTRONIC DEVICE MANUFACTURING METHOD

(71) Applicant: Gigaphoton Inc., Oyama-shi (JP)

(72) Inventor: Hiroaki MOTOSUGI, Oyama-shi (JP)

(73) Assignee: Gigaphoton Inc., Oyama-shi (JP)

(21) Appl. No.: 19/292,665

(22) Filed: Aug. 6, 2025

(30) Foreign Application Priority Data
Sep. 17, 2024 (JP) 2024-160149

(51) Int. Cl. H01S 5/00; G02F 1/35; G02F 1/39; G03F 7/00; H01S 3/23

(52) U.S. Cl. CPC H01S 5/0092; G02F 1/3534; G02F 1/392; G03F 7/70025; G03F 7/70041; G03F 7/705; G03F 7/70575; H01S 3/2308; H01S 5/0085

(57) ABSTRACT

A spectral linewidth adjusting method includes: adjusting a timing of a first trigger signal for amplifying and converting a portion of a first pulse laser beam to a second pulse laser beam and/or a timing of a second trigger signal for amplifying and converting a portion of second continuous light to a third pulse laser beam and adjusting a spectrum of a fourth pulse laser beam obtained by performing sum-frequency mixing of the second and third pulse laser beams to a first spectrum in a non-Gaussian shape; and modulating a wavelength of the second continuous light within time corresponding to one pulse of the third pulse laser beam and adjusting the spectrum of the fourth pulse laser beam to a second spectrum having a spectral linewidth wider than the first spectrum through generation of a modulation signal for supplying the modulation signal to an optical phase modulator.

### CROSS-REFERENCE TO RELATED APPLICATIONS

The present application claims the benefit of Japanese Patent Application No. JP2024-160149, filed on Sep. 17, 2024, the entire contents of which are hereby incorporated by reference.

### BACKGROUND

### 1. Technical Field

The present disclosure relates to a spectral linewidth adjusting method and an electronic device manufacturing method.

### 2. Related Art

Recently, in a semiconductor exposure apparatus, improvement in resolution has been desired for miniaturization and high integration of semiconductor integrated circuits. For this purpose, an exposure light source that outputs light having a shorter wavelength has been developed. For example, as a gas laser apparatus for exposure, a KrF excimer laser apparatus that outputs a laser beam having a wavelength of about 248 nm and an ArF excimer laser apparatus that outputs a laser beam having a wavelength of about 193 nm are used.

Spectral linewidths of spontaneous oscillation beams of the KrF excimer laser apparatus and the ArF excimer laser apparatus are as wide as from 350 pm to 400 pm. Therefore, when a projection lens is formed of a material that transmits ultraviolet light such as KrF and ArF laser beams, chromatic aberration may occur. As a result, the resolution may decrease. Thus, the spectral linewidth of the laser beam output from the gas laser apparatus needs to be narrowed to an extent that the chromatic aberration is ignorable. Therefore, in a laser resonator of the gas laser apparatus, a line narrowing module (LNM) including a line narrowing element (such as etalon or grating) may be provided in order to narrow the spectral linewidth. Hereinafter, a gas laser apparatus with a narrowed spectral linewidth is referred to as a line narrowing gas laser apparatus.

### LIST OF DOCUMENTS

### Patent Documents

Patent Document 1: International Publication No. WO2024/057673

Patent Document 2: Japanese Unexamined Patent Application Publication No. 2010-238684

### SUMMARY

A spectral linewidth adjusting method according to one aspect of the present disclosure is for a pulse laser beam output by a laser apparatus. The laser apparatus includes a first semiconductor laser configured to output first continuous light, a first amplifier configured to amplify a portion of the first continuous light in synchronization with a light emission trigger signal received from an external device and to convert the portion of the first continuous light to a first pulse laser beam, a second amplifier configured to amplify a portion of the first pulse laser beam using a first trigger signal generated in synchronization with the light emission trigger signal and to convert the portion of the first pulse laser beam to a second pulse laser beam, a second semiconductor laser configured to output second continuous light, a third amplifier configured to amplify a portion of the second continuous light using a second trigger signal generated in synchronization with the light emission trigger signal and to convert the portion of the second continuous light to a third pulse laser beam, an optical phase modulator disposed in an optical path of the second continuous light between the second semiconductor laser and the third amplifier, a modulation signal generator configured to output a modulation signal to be supplied to the optical phase modulator, and a wavelength conversion system configured to perform sum-frequency mixing of the second pulse laser beam and the third pulse laser beam for wavelength conversion and to output a fourth pulse laser beam. The spectral linewidth adjusting method includes a first step and a second step. In the first step, at least one of a timing of the first trigger signal and a timing of the second trigger signal is adjusted and a spectrum of the fourth pulse laser beam is adjusted to a first spectrum in a non-Gaussian shape. In the second step, a wavelength of the second continuous light is modulated within time corresponding to one pulse of the third pulse laser beam and the spectrum of the fourth pulse laser beam is adjusted to a second spectrum having a spectral linewidth wider than the first spectrum by causing the modulation signal generator to generate the modulation signal of a same pattern synchronized with the light emission trigger signal and supplying the modulation signal of the same pattern to the optical phase modulator.

An electronic device manufacturing method according to another aspect of the present disclosure includes generating a fourth pulse laser beam by a laser apparatus, outputting the fourth pulse laser beam to an exposure apparatus, and exposing a photosensitive substrate to the fourth pulse laser beam within the exposure apparatus to manufacture an electronic device. The laser apparatus includes a first semiconductor laser configured to output first continuous light, a first amplifier configured to amplify a portion of the first continuous light in synchronization with a light emission trigger signal received from an external device and to convert the portion of the first continuous light to a first pulse laser beam, a second amplifier configured to amplify a portion of the first pulse laser beam using a first trigger signal generated in synchronization with the light emission trigger signal and to convert the portion of the first pulse laser beam to a second pulse laser beam, a second semiconductor laser configured to output second continuous light, a third amplifier configured to amplify a portion of the second continuous light using a second trigger signal generated in synchronization with the light emission trigger signal and to convert the portion of the second continuous light to a third pulse laser beam, an optical phase modulator disposed in an optical path of the second continuous light between the second semiconductor laser and the third amplifier, a modulation signal generator configured to output a modulation signal to be supplied to the optical phase modulator, and a wavelength conversion system configured to perform sum-frequency mixing of the second pulse laser beam and the third pulse laser beam for wavelength conversion and to output the fourth pulse laser beam. The laser apparatus adjusts at least one of a timing of the first trigger signal and a timing of the second trigger signal, and adjusts a spectrum of the fourth pulse laser beam to a first spectrum in a non-Gaussian shape. The laser apparatus modulates a wavelength of the second continuous light within time corresponding to one pulse of the third pulse laser beam and adjusts the spectrum of the fourth pulse laser beam to a second spectrum having a spectral linewidth wider than the first spectrum by causing the modulation signal generator to generate the modulation signal of a same pattern synchronized with the light emission trigger signal and supplying the modulation signal of the same pattern to the optical phase modulator.

### BRIEF DESCRIPTION OF THE DRAWINGS

Some embodiments of the present disclosure will be described below, by way of example only, with reference to the accompanying drawings.

FIG. 1 schematically illustrates a configuration of a laser apparatus according to a comparative example.

FIG. 2 schematically illustrates a configuration of a solid-state seeder.

FIG. 3 illustrates an example of a pseudorandom signal generator.

FIG. 4 illustrates a flowchart of a control example of a spectral linewidth in the comparative example.

FIG. 5 illustrates a flowchart of another control example of the spectral linewidth in the comparative example.

FIG. 6 schematically illustrates a configuration of a laser apparatus according to Embodiment 1.

FIG. 7 schematically illustrates a configuration of a solid-state seeder.

FIG. 8 illustrates a timing chart at the time of laser operation execution.

FIG. 9 illustrates a flowchart at the time of timing adjustment.

FIG. 10 illustrates a flowchart of a first step of Embodiment 1.

FIG. 11 illustrates a timing chart in the first step.

FIG. 12 illustrates a spectrum of a fourth pulse laser beam in adjustment in the first step.

FIGS. 13A and 13B illustrate determination examples of a non-Gaussian waveform.

FIG. 14 illustrates a flowchart of a second step.

FIG. 15 illustrates a spectrum of a fourth pulse laser beam after a search in the second step.

FIG. 16 illustrates a flowchart of a first step of Embodiment 2.

FIG. 17 illustrates a spectrum of a fourth pulse laser beam in adjustment in the first step.

FIG. 18 illustrates a spectrum of a fourth pulse laser beam after a search in the second step.

FIG. 19 illustrates a flowchart of a first step of Embodiment 3.

FIG. 20 illustrates a spectrum of a fourth pulse laser beam in adjustment in the first step.

FIG. 21 illustrates a spectrum of a fourth pulse laser beam after a search in the second step.

FIG. 22 schematically illustrates a configuration example of an exposure apparatus.

### DESCRIPTION OF EMBODIMENTS

### Contents

1. Comparative Example
   1.1 Laser Apparatus
      1.1.1 Configuration
      1.1.2 Operation
   1.2 Configuration of Pseudorandom Signal Generator
   1.3 Example 1 of Pseudorandom Signal Generator Operation
   1.4 Effect and Advantage
   1.5 Example 2 of Pseudorandom Signal Generator Operation
   1.6 Effect and Advantage
   1.7 Problem
2. Embodiment 1
   2.1 Configuration
      2.1.1 Laser Apparatus
      2.1.2 Solid-State Seeder
   2.2 Operation
      2.2.1 Time of Laser Operation Execution
      2.2.2 Time of Adjustment
      2.2.2.1 First Step
      2.2.2.2 Second Step
   2.3 Effect and Advantage
3. Embodiment 2
   3.1 Configuration
   3.2 Operation
   3.3 Effect and Advantage
4. Embodiment 3
   4.1 Configuration
   4.2 Operation
   4.3 Effect and Advantage
5. Electronic Device Manufacturing Method
6. Others

Hereinafter, embodiments of the present disclosure will be described in detail with reference to the drawings. The embodiments described below show some examples of the present disclosure and do not limit contents of the present disclosure. In addition, all configurations and operations described in the embodiments are not necessarily essential as configurations and operations of the present disclosure. Here, the same components are denoted by the same reference signs, and any redundant description thereof is omitted.

### 1. Comparative Example

### 1.1 Laser Apparatus

### 1.1.1 Configuration

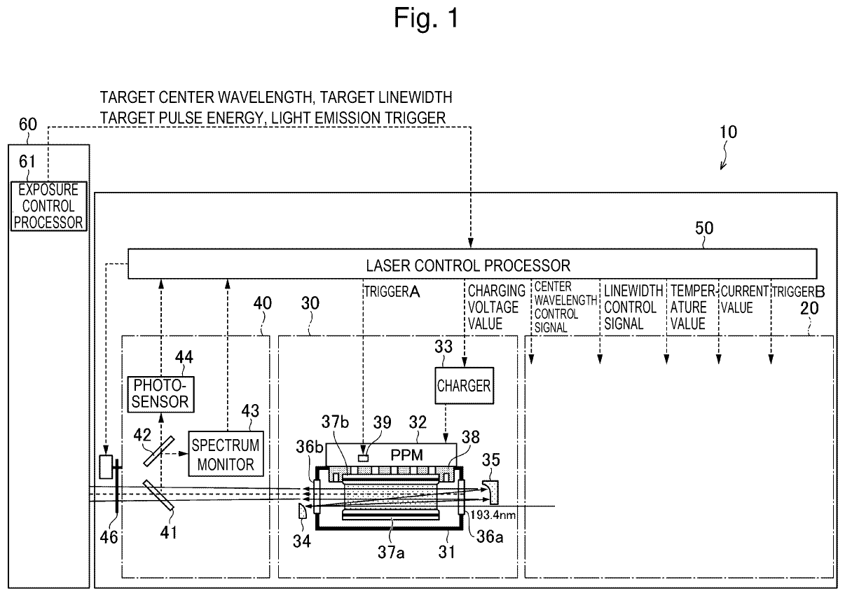

FIG. 1 schematically illustrates a configuration of a laser apparatus 10 according to a comparative example. The comparative example of the present disclosure is an example recognized by the applicant as known only by the applicant, and is not a publicly known example admitted by the applicant.

The laser apparatus 10 includes a solid-state seeder 20 as a master oscillator (MO) that generates a pulse laser beam, an excimer amplifier 30 as a power amplifier (PA) that amplifies output light of the solid-state seeder 20, a monitor module 40, an exit shutter 46, and a laser control processor 50.

The solid-state seeder 20 outputs a pulse laser beam having a central wavelength of about 193.4 nm.

The excimer amplifier 30 includes a chamber 31, a pulse power module (PPM) 32, a charger 33, a convex mirror 34, and a concave mirror 35. The chamber 31 includes windows 36a and 36b, a pair of electrodes 37a and 37b, and an electric insulating member 38. Inside the chamber 31, an ArF laser gas is supplied from an unillustrated gas supply device. The ArF laser gas includes an Ar gas, an F2 gas, and an Ne gas.

The PPM 32 includes a switch 39 and an unillustrated charging capacitor. The charger 33 holds electric energy to be supplied to the PPM 32. The charger 33 is connected to the unillustrated charging capacitor. The charger 33 charges the charging capacitor of the PPM 32 in accordance with a command from the laser control processor 50.

The PPM 32 is connected with the electrode 37b in the chamber 31 via a feedthrough in the electric insulating member 38. The electrode 37a is connected to a ground potential.

The windows 36a and 36b are disposed such that a pulse laser beam amplified by discharge excitation between the electrodes 37a and 37b passes through.

The convex mirror 34 and the concave mirror 35 are disposed such that the pulse laser beam output from the solid-state seeder 20 passes through a discharge space between the electrodes 37a and 37b three times so as to expand the beam.

The monitor module 40 includes beam splitters 41 and 42, a spectrum monitor 43, and a photosensor 44. The beam splitter 41 is disposed such that, on an optical path of the pulse laser beam output from the excimer amplifier 30, the pulse laser beam reflected by the beam splitter 41 enters the beam splitter 42. The beam splitter 41 may be disposed outside the monitor module 40.

The beam splitter 42 is disposed such that the pulse laser beam reflected by the beam splitter 42 enters the spectrum monitor 43 and the pulse laser beam transmitted through the beam splitter 42 enters the photosensor 44.

The spectrum monitor 43 monitors a spectrum of the incident pulse laser beam, and detects an oscillation wavelength of the incident pulse laser beam. The spectrum monitor 43 may be, for example, an etalon spectrometer. The etalon spectrometer includes a diffusion plate that diffuses sample light, an etalon, a light condensing lens disposed on an exit side of the etalon, and a photodiode array disposed on a focal plane of the light condensing lens for detecting a pattern of interference fringes, and can detect the wavelength by measuring a diameter of the interference fringes.

The photosensor 44 detects pulse energy of the incident pulse laser beam. The photosensor 44 may be, for example, a photodiode.

The exit shutter 46 is disposed on an optical path of the pulse laser beam output from the laser apparatus 10 to the outside, and is configured so as to switch between output of the pulse laser beam to the outside and light shielding. The pulse laser beam transmitted through the beam splitter 41 is output from the laser apparatus 10 via the exit shutter 46.

The laser apparatus 10 is connected with an exposure apparatus 60 via an unillustrated beam delivery unit (BDU). The BDU is an optical system that transmits the pulse laser beam from the laser apparatus 10 to the exposure apparatus 60. The pulse laser beam output from the laser apparatus 10 enters the exposure apparatus 60 via the BDU.

The exposure apparatus 60 includes an exposure control processor 61. The exposure control processor 61 controls the exposure apparatus 60. In addition, the exposure control processor 61 is connected with the laser control processor 50. The exposure apparatus 60 is an example of an “external device” in the present disclosure.

The laser control processor 50 receives a target center wavelength, a target linewidth, target pulse energy, and a light emission trigger signal from the exposure control processor 61. The laser control processor 50 sends a trigger A signal and a charging voltage value to the excimer amplifier 30 and a trigger B signal, a linewidth control signal, a temperature value, and a current value to the solid-state seeder 20 to operate the laser apparatus 10, and controls the pulse laser beam. In the present specification, a processor is a processing device including a storage device in which a control program is stored, and a CPU (Central Processing Unit) which executes the control program. The processor is specifically configured or programmed to execute various kinds of processing included in the present disclosure.

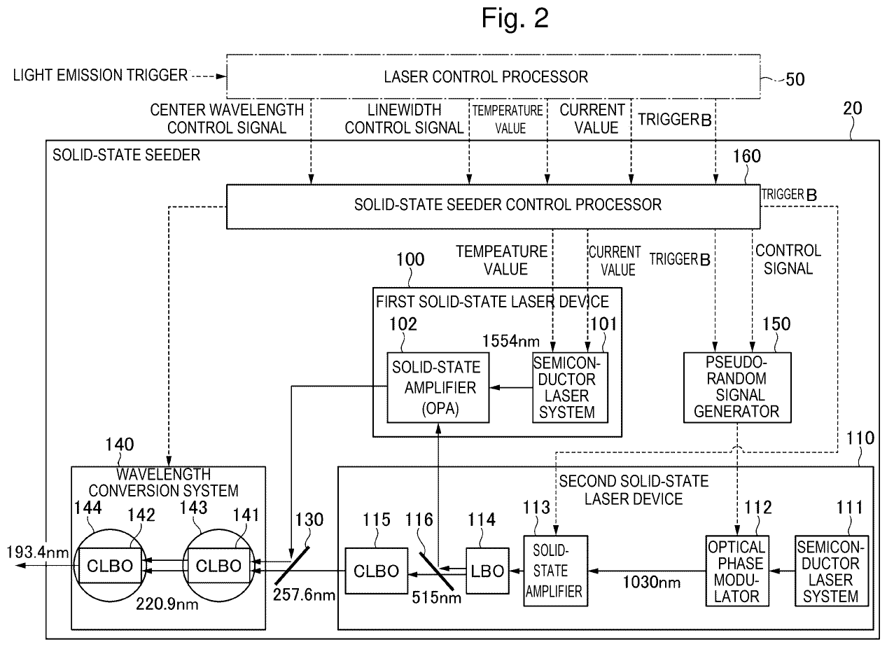

FIG. 2 schematically illustrates a configuration of the solid-state seeder 20. The solid-state seeder 20 includes a first solid-state laser device 100, a second solid-state laser device 110, a dichroic mirror 130, a wavelength conversion system 140, a pseudorandom signal generator 150, and a solid-state seeder control processor 160.

The solid-state seeder 20 has a system configuration in which a pulse laser beam having a wavelength of about 1554 nm output from the first solid-state laser device 100 and a pulse laser beam having a wavelength of about 257.6 nm output from the second solid-state laser device 110 are converted to a pulse laser beam having a wavelength of about 193.4 nm through two-stage sum-frequency mixing in the wavelength conversion system 140.

The first solid-state laser device 100 includes a semiconductor laser system 101 and a solid-state amplifier 102. The semiconductor laser system 101 includes a first semiconductor laser configured to CW (Continuous Wave) oscillate in a single longitudinal mode at the wavelength of about 1554 nm, and to output first continuous light.

The solid-state amplifier 102 may be an optical parametric amplifier (OPA). The OPA is, for example, PPLN (periodically poled lithium niobate: periodically poled lithium niobate crystal) or PPKTP (periodically poled KTP: periodically poled titanyl potassium phosphate crystal).

The solid-state amplifier 102 is configured to pulse-amplify seed light by receiving input of a pulse laser beam having a wavelength of 1030 nm to be described later as pump light and a laser beam output from the semiconductor laser system 101 as the seed light.

The second solid-state laser device 110 includes a semiconductor laser system 111, an optical phase modulator 112, a solid-state amplifier 113, an LBO crystal 114 and a CLBO crystal 115 which are two nonlinear crystals that perform second harmonic generation twice and perform wavelength conversion so that an optical frequency is quadrupled, and a dichroic mirror 116. The “LBO” is represented by a chemical formula LiB3O5. The “CLBO” is represented by a chemical formula CsLiB6O10.

The semiconductor laser system 111 includes a second semiconductor laser configured to CW oscillate in the single longitudinal mode at the wavelength of about 1030 nm, and to output second continuous light.

The solid-state amplifier 113 may include, for example, a Yb fiber amplifier and a Yb:YAG crystal. The solid-state amplifier 113 may be configured same as the solid-state amplifier 102.

The optical phase modulator 112 is disposed on an optical path between the semiconductor laser system 111 and the solid-state amplifier 113.

The dichroic mirror 116 is disposed on an optical path between the LBO crystal 114 and the CLBO crystal 115, highly transmits the pulse laser beam having the wavelength of about 515 nm, and highly reflects the pulse laser beam having the wavelength of about 1030 nm. The dichroic mirror 116 is disposed such that the highly reflected pulse laser beam having the wavelength of about 1030 nm enters the solid-state amplifier 102 as the pump light. An unillustrated beam splitter may be disposed between the solid-state amplifier 113 and the LBO crystal 114 instead of the dichroic mirror 116 so that the pulse laser beam output from the solid-state amplifier 113 is branched to enter the LBO crystal 114 and the solid-state amplifier 102.

The dichroic mirror 130 is configured to highly reflect the pulse laser beam having the wavelength of about 1554 nm output from the first solid-state laser device 100 and to highly transmit the pulse laser beam having the wavelength of about 257.6 nm output from the second solid-state laser device 110, and is disposed such that both pulse laser beams coaxially enter the wavelength conversion system 140.

The wavelength conversion system 140 includes a CLBO crystal 141, a CLBO crystal 142, a rotation stage 143, and a rotation stage 144. The CLBO crystal 141 and the CLBO crystal 142 are disposed on the rotation stage 143 and the rotation stage 144, each including a piezoelectric element, so that an incident angle of each crystal can be changed at a high speed.

The pseudorandom signal generator 150 outputs a modulation signal to be supplied to the optical phase modulator 112. The pseudorandom signal generator 150 is formed of a multi-stage shift register and a variable bandpass filter (digital filter) both of which are not illustrated in FIG. 2.

The solid-state seeder control processor 160 controls a wavelength, power, a pulse waveform, a spectrum, and the like of the laser beam output by the solid-state seeder 20. The solid-state seeder control processor 160 controls the first solid-state laser device 100, the second solid-state laser device 110, the dichroic mirror 130, the wavelength conversion system 140, and the pseudorandom signal generator 150 based on input from the laser control processor 50.

### 1.1.2 Operation

In the solid-state seeder 20, by fixing the wavelength of the pulse laser beam output from the second solid-state laser device 110 and changing the wavelength of the pulse laser beam output from the first solid-state laser device 100 for each pulse, the wavelength of the pulse laser beam output from the wavelength conversion system 140 can be changed.

The operation of the second solid-state laser device 110 is as follows. The solid-state seeder control processor 160 fixes an oscillation wavelength of the second solid-state laser device 110 at 1030 nm. That is, the solid-state seeder control processor 160 fixes a current value of the second semiconductor laser in the semiconductor laser system 111, causes the second semiconductor laser to continuously oscillate, and causes a CW laser beam to be output from the second semiconductor laser.

The CW laser beam output from the semiconductor laser system 111 is phase-modulated by the optical phase modulator 112 and enters the solid-state amplifier 113.

The solid-state seeder control processor 160 transmits a timing signal same as the trigger B signal acquired from the laser control processor 50 and a reset signal to the shift register of the pseudorandom signal generator 150 to the pseudorandom signal generator 150.

The pseudorandom signal generator 150 receives the reset signal from the solid-state seeder control processor 160 to the shift register and generates a pseudorandom signal of a same pattern in synchronization with the trigger B signal.

From the pseudorandom signal, unneeded spectral components of high frequency components are eliminated by the variable bandpass filter.

The optical phase modulator 112 phase-modulates the CW laser beam with the pseudorandom signal limited to an appropriate frequency band from the pseudorandom signal generator 150 to change the spectrum.

When a cutoff frequency of the variable bandpass filter of the pseudorandom signal generator 150 is changed to a high frequency side, a spectral linewidth of the light becomes wide, and when it is changed to a low frequency side, the spectral linewidth becomes narrow. In addition, the waveform and the spectrum of the pseudorandom signal are changed by changing a timing of inputting the reset signal to the shift register of the pseudorandom signal generator 150 as well, and the spectral linewidth of the laser beam output from the optical phase modulator 112 is also changed.

When the spectral linewidth is to be controlled, the spectral linewidth of the laser beam is measured, and a frequency of the pseudorandom signal is adjusted based on the measured spectral linewidth. Specifically, the cutoff frequency of the variable bandpass filter is adjusted.

The solid-state seeder control processor 160 pulse-amplifies the CW laser beam phase-modulated by the optical phase modulator 112 by the solid-state amplifier 113 in synchronization with the trigger B signal. The solid-state amplifier 113 outputs the pulse laser beam having the wavelength of 1030 nm.

The pulse laser beam having the wavelength of 1030 nm output from the solid-state amplifier 113 is converted to second harmonic light having the wavelength of 515 nm in the LBO crystal 114. The second harmonic light having the wavelength of 515 nm is highly transmitted through the dichroic mirror 116 and is converted to the pulse laser beam having the wavelength of 257.6 nm by the CLBO crystal 115. The LBO crystal 114 and the CLBO crystal 115 are examples of a “wavelength conversion crystal” in the present disclosure.

Here, the dichroic mirror 116 highly reflects the pulse laser beam having the wavelength of 1030 nm, which has not been wavelength-converted in the LBO crystal 114, to make it enter the solid-state amplifier 102 of the first solid-state laser device 100 as the pump light.

On the other hand, the laser control processor 50 and the solid-state seeder control processor 160 can change the wavelength of the pulse laser beam output from the first solid-state laser device 100 around 1554 nm by controlling a temperature value and/or a current value of the first semiconductor laser in the semiconductor laser system 101 of the first solid-state laser device 100. The solid-state seeder control processor 160 may change the oscillation wavelength of the semiconductor laser system 101 for each pulse.

The pulse laser beam having the wavelength of about 1554 nm output from the first solid-state laser device 100 and the pulse laser beam having the wavelength of 257.6 nm output from the second solid-state laser device 110 are subjected to sum-frequency mixing by the CLBO crystal 141 of the wavelength conversion system 140, and wavelength-converted to the pulse laser beam having the wavelength of about 220.9 nm. Furthermore, by the CLBO crystal 142, the pulse laser beam having the wavelength of about 220.9 nm and the pulse laser beam having the wavelength of about 1554 nm are subjected to sum-frequency mixing, and is wavelength-converted to the pulse laser beam having the wavelength of about 193.4 nm. Then, the pulse laser beam having the wavelength of about 193.4 nm is output from the wavelength conversion system 140.

A variable range of the wavelength of the pulse laser beam output from the solid-state seeder 20 is from about 193.2 nm to 193.5 nm as an amplification wavelength band of the excimer amplifier 30.

As discharge occurs in synchronization with entry of the pulse laser beam output from the solid-state seeder 20 to the discharge space of the chamber 31 of the excimer amplifier 30, the trigger A signal is input to the switch 39 of the PPM 32. As a result, the pulse laser beam output from the solid-state seeder 20 is amplified by the excimer amplifier 30 through three-time passing.

The pulse laser beam amplified by the excimer amplifier 30 is sampled by the beam splitter 41 and the beam splitter 42 of the monitor module 40, and the spectrum and the pulse energy are measured by the spectrum monitor 43 and the photosensor 44.

From the measured spectrum of the pulse laser beam output from the excimer amplifier 30, the laser control processor 50 sends a center wavelength control signal to the solid-state seeder control processor 160 so that a center wavelength approaches the target center wavelength which is a target value. The solid-state seeder control processor 160 sends a command value of the temperature value and the current value to the semiconductor laser system 101 based on the control signal acquired from the laser control processor 50. The semiconductor laser system 101 changes a temperature or a current of the semiconductor laser of the semiconductor laser system 101 to change the oscillation wavelength based on the command value of the temperature value and the current value acquired from the solid-state seeder control processor 160.

Further, from the measured spectrum of the pulse laser beam output from the excimer amplifier 30, the laser control processor 50 sends a spectral linewidth control signal to the solid-state seeder control processor 160 so that the spectral linewidth approaches the target linewidth which is the target value. The solid-state seeder control processor 160 changes a signal bandwidth and power of the modulation signal output from the pseudorandom signal generator 150 based on the control signal acquired from the laser control processor 50.

The optical phase modulator 112 changes the spectral linewidth of the laser beam output from the optical phase modulator 112 by the signal bandwidth and the power of output from the pseudorandom signal generator 150.

Further, the laser control processor 50 changes a charging voltage of the charger 33 so that the measured pulse energy of the pulse laser beam output from the excimer amplifier 30 approaches the target pulse energy which is the target value.

By the configuration and the operation, the wavelength of the second continuous light is modulated within time corresponding to one pulse of the pulse laser beam, and the spectral linewidth of the pulse laser beam is adjusted. The pseudorandom signal of the same pattern is generated in synchronization with the trigger B signal synchronized with the timing of generation of the pulse laser beam, and is superimposed onto the optical phase modulator 112. Therefore, the modulation signal of the same waveform for each pulse is superimposed onto the optical phase modulator 112, and the spectrum of the superimposed signal is also the same for each pulse.

Thus, since the pulse laser beam output from the optical phase modulator 112 is modulated the same for each pulse, the spectrum becomes the same for each pulse, and the spectral linewidth also becomes the same for each pulse and becomes stable.

Note that when the spectrum is changed by operating the pseudorandom signal generator 150 in synchronization with the trigger B signal, in order to make its shape unimodal, a flow of a search to update an initial value of the shift register until the spectrum becomes unimodal is required.

### 1.2 Configuration of Pseudorandom Signal Generator

An initial value setting circuit is added to the pseudorandom signal generator, and the initial value of the shift register is adjusted so that the generated spectrum becomes unimodal.

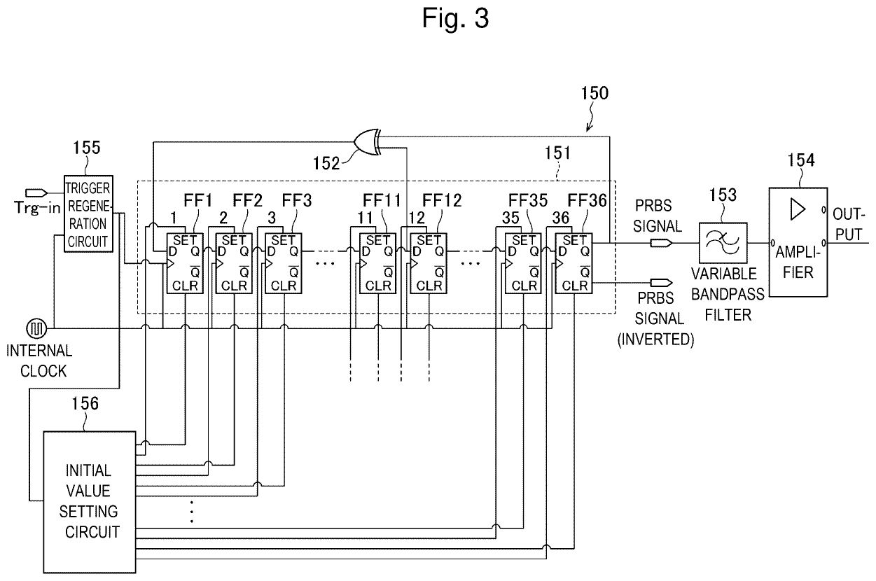

FIG. 3 illustrates an example of the pseudorandom signal generator 150. The pseudorandom signal generator 150 includes a shift register 151, at least one exclusive OR (XOR) circuit 152, a variable bandpass filter 153, an amplifier 154, a trigger regeneration circuit 155, and an initial value setting circuit 156.

The shift register 151 is configured such that 36 D flip-flops FF1 to FF36 are connected in series, Q output of the D flip-flop FF11 of an 11th stage and Q output of the D flip-flop FF36 of a 36th stage are input to the XOR circuit 152, and output of the XOR circuit 152 is fed back to the D flip-flop FF1 of a 1st stage. The Q output of the D flip-flop FF36 of the 36th stage repeats a same random pattern (pseudorandom pattern) every time a clock is counted 2³⁶−1 times (period 2³⁶−1). The Q output of the D flip-flop FF36 of the 36th stage is input to the variable bandpass filter 153, and the output of the variable bandpass filter 153 is amplified and output by the amplifier 154. A passband of the variable bandpass filter 153 and output power of the amplifier 154 are controlled by control signals from the solid-state seeder control processor 160.

The trigger regeneration circuit 155 generates a timing signal that changes an initial value of the D flip-flops FF1 to FF36 from the trigger B signal from the solid-state seeder control processor 160 and a high-speed internal clock of the pseudorandom signal generator 150.

In the initial value setting circuit 156, a signal is sent to a SET terminal or a CLR terminal of each of the D flip-flops FF1 to FF36 so that the initial value of each of the D flip-flops FF1 to FF36 is “0” or “1” (“Low” or “Hi”) by the control signal from the solid-state seeder control processor 160 in synchronization with the timing signal generated by the trigger regeneration circuit 155. For example, when the initial value is to be set to “0”, the signal is sent to the CLR terminal, and when the initial value is to be set to “1”, the signal is sent to the SET terminal.

While an example using D flip-flops in 36 stages has been described here, the number of stages of the D flip-flops is not limited to this example, and the number of stages, a feedback position, and the number of XOR circuits 152 may be appropriately arranged and connected according to a well-known feedback polynomial, for example. Further, the shift register 151 formed of the D flip-flops in multiple stages may be formed of an FPGA (Field Programmable Gate Array) or the like. In addition, while the power of the modulation signal to be output is adjusted in the amplifier 154 here, output power may be adjusted by inserting a variable attenuator in a succeeding stage or a preceding stage of the amplifier 154.

An XNOR circuit may be used instead of the XOR circuit 152. The pseudorandom signal generator 150 is an example of a “modulation signal generator” in the present disclosure.

### 1.3 Example 1 of Pseudorandom Signal Generator Operation

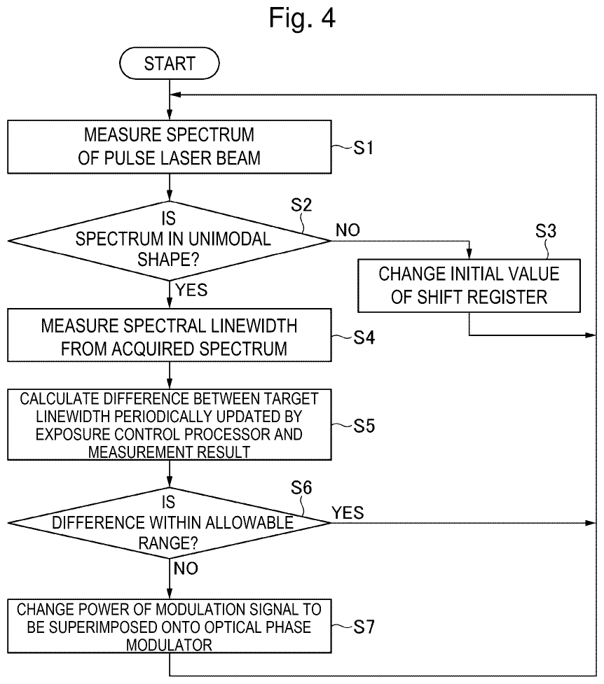

FIG. 4 illustrates a flowchart of a control example of the spectral linewidth in the comparative example. In step S1, the laser control processor 50 measures a spectrum of an output pulse laser beam of the excimer amplifier 30 using the spectrum monitor 43 of the monitor module 40.

In step S2, the laser control processor 50 examines whether the measured spectrum is unimodal or multimodal and determines whether the spectrum has a unimodal shape. If a determination result in step S2 is NO determination, that is, if the spectrum is multimodal, the laser control processor 50 proceeds to step S3.

In step S3, the laser control processor 50 changes the initial value of the shift register 151 via the solid-state seeder control processor 160 and returns to step S1.

On the other hand, if the determination result in step S2 is YES determination, that is, if the spectrum is unimodal, the laser control processor 50 proceeds to step S4.

In step S4, the laser control processor 50 measures the spectral linewidth from the acquired spectrum.

In step S5, the laser control processor 50 calculates a difference between the target linewidth, which is periodically updated by the exposure control processor 61, and a measurement result in step S4.

In step S6, the laser control processor 50 determines whether the calculated difference is within an allowable range. If a determination result in step S6 is YES determination, that is, if the difference is within the allowable range, the laser control processor 50 returns to step S1.

On the other hand, if the determination result in step S6 is NO determination, that is, if the difference is not within the allowable range, the laser control processor 50 proceeds to step S7.

In step S7, the laser control processor 50 determines the power of the modulation signal by a function indicating a relationship between a square root of the power of the modulation signal and the spectral linewidth obtained in advance and the difference calculated in step S5, changes the power of the modulation signal to be superimposed onto the optical phase modulator 112, and returns to step S1. However, instead of the relationship between the square root of the power of the modulation signal and the spectral linewidth obtained in advance, a table list of the relationship between the square root of the power of the modulation signal and the spectral linewidth that has been recorded may be used. Alternatively, instead of adjusting the power of the modulation signal, the bandwidth of the modulation signal may be adjusted using the variable bandpass filter 153.

### 1.4 Effect and Advantage

Adjusting the initial value of the shift register 151 allows control to be the target spectral linewidth with the unimodal spectrum at all times.

Since the relationship between the square root of the power of the modulation signal and the spectral linewidth has high linearity, linewidth control can be executed more easily and accurately by adjusting the power of the modulation signal.

Further, since the relationship between the bandwidth of the modulation signal and the spectral linewidth has high linearity, the linewidth control can be executed more easily and accurately by adjusting the bandwidth of the modulation signal.

### 1.5 Example 2 of Pseudorandom Signal Generator Operation

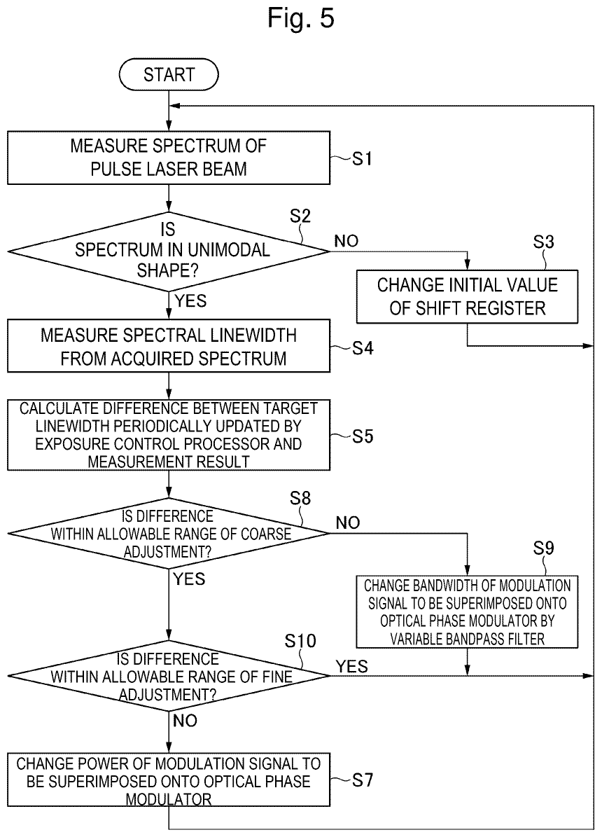

FIG. 5 illustrates a flowchart of another control example of the spectral linewidth in the comparative example. In this example, the spectral linewidth is coarsely adjusted by the bandwidth of the modulation signal and finely adjusted by the power of the modulation signal. Processing of steps S1 to S5 is the same as that in the flowchart illustrated in FIG. 4.

In step S8 following step S5, the laser control processor 50 determines whether the difference calculated in step S5 is within the allowable range of coarse adjustment. If a determination result in step S8 is NO determination, that is, if the difference is not within the allowable range of the coarse adjustment, the laser control processor 50 proceeds to step S9.

In step S9, the laser control processor 50 changes the bandwidth of the modulation signal to be superimposed onto the optical phase modulator 112 by the variable bandpass filter 153. The operation in step S9 may be performed by the solid-state seeder control processor 160 in accordance with a command of the laser control processor 50. After step S9, the laser control processor 50 returns to step S1.

If the determination result in step S8 is YES determination, that is, if the difference is within the allowable range of the coarse adjustment, the laser control processor 50 proceeds to step S10. In step S10, the laser control processor 50 determines whether the difference calculated in step S5 is within the allowable range of fine adjustment. If a determination result in step S10 is YES determination, that is, if the difference is within the allowable range of the fine adjustment, the laser control processor 50 returns to step S1.

If the determination result in step S10 is NO determination, that is, if the difference is not within the allowable range of the fine adjustment, the laser control processor 50 proceeds to step S7. The processing of step S7 is the same as that in the flowchart illustrated in FIG. 4. After step S7, the laser control processor 50 returns to step S1. The operation in step S7 may be performed by the solid-state seeder control processor 160 in accordance with a command of the laser control processor 50.

### 1.6 Effect and Advantage

Adjusting the initial value of the shift register 151 allows the control to be the target spectral linewidth with the unimodal spectrum at all times. Further, since a method of changing the bandwidth of the modulation signal when the spectral linewidth is coarsely adjusted and changing the power of the modulation signal when the spectral linewidth is finely adjusted is adopted, an amount of changing the power of the modulation signal is small as compared with a case where the linewidth is controlled only by the power of the modulation signal. Thus, stability of the entire modulation signal generator including the pseudorandom signal generator 150 is improved, a thermal load or the like applied to the optical phase modulator 112 is reduced, and stable control is made possible.

Further, as compared with a case where the linewidth is controlled only by the bandwidth of the modulation signal, when the change of the power of the modulation signal is used, a set resolution can be made finer.

### 1.7 Problem

In technology of adjusting the spectrum of the laser beam by the pseudorandom signal generator 150 formed of the multi-stage shift register 151 and the variable bandpass filter 153 and the optical phase modulator 112, when the spectral linewidth defined by a full width at half maximum (FWHM), an E95 width, or the like is to be widened while maintaining unimodality of a Gaussian waveform or the like, since magnitude of an amplitude of optical phase modulation is finite, an adjustment range of the spectral linewidth (an upper limit of the spectral linewidth in particular) is limited.

For example, when the spectral linewidth on a wide side such as 0.5 pm with respect to the E95 linewidth of 0.2 pm or more and 0.5 pm or less or the like, which is demanded for semiconductor lithography, is to be obtained, it has been difficult to obtain a sufficiently wide spectral linewidth by the optical phase modulation alone.

### 2. Embodiment 1

### 2.1 Configuration

### 2.1.1 Laser Apparatus

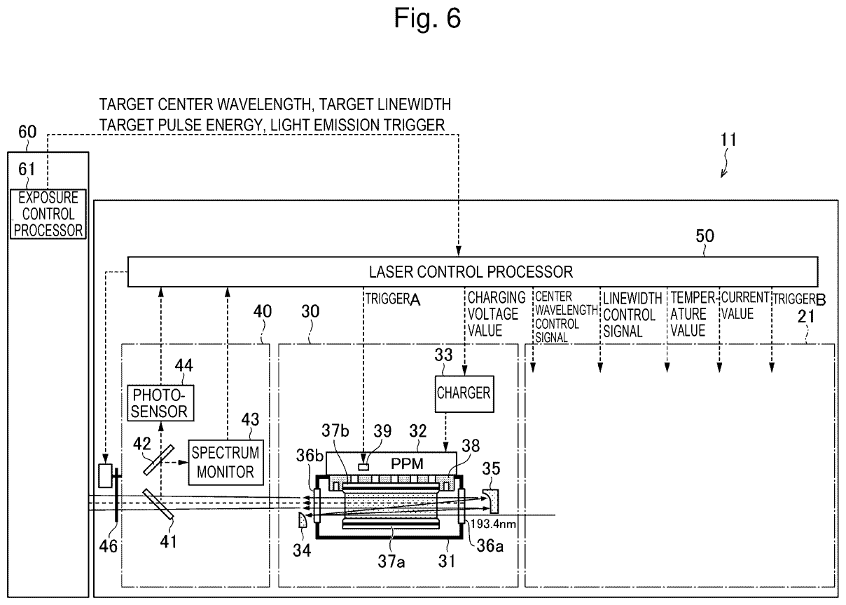

FIG. 6 schematically illustrates a configuration of a laser apparatus 11 according to Embodiment 1. The configuration illustrated in FIG. 6 will be described in terms of differences from the configuration illustrated in FIG. 1. The laser apparatus 11 includes a solid-state seeder 21 instead of the solid-state seeder 20 in FIG. 1.

### 2.1.2 Solid-State Seeder

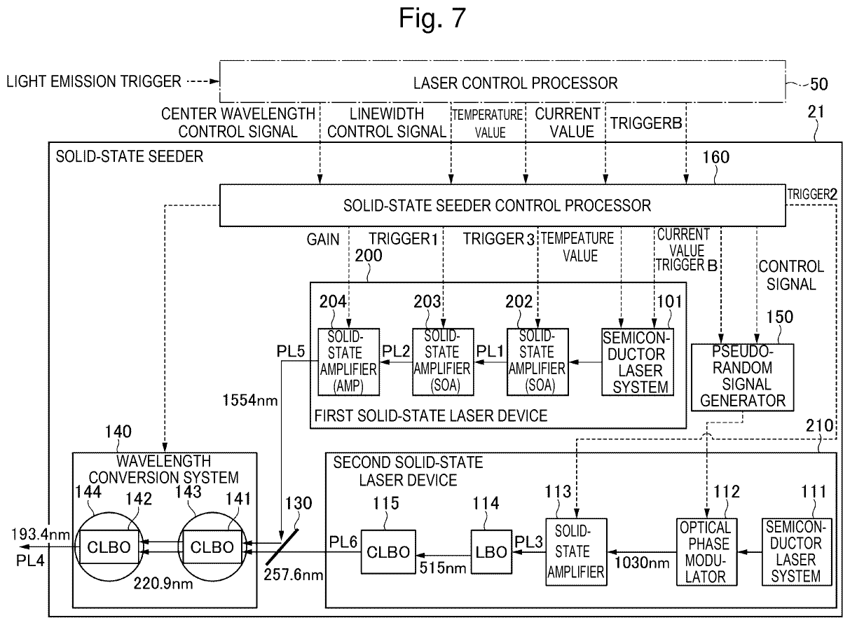

FIG. 7 schematically illustrates a configuration of the solid-state seeder 21. The configuration illustrated in FIG. 7 will be described in terms of differences from the configuration illustrated in FIG. 2. The solid-state seeder 21 includes a first solid-state laser device 200 and a second solid-state laser device 210 instead of the first solid-state laser device 100 and the second solid-state laser device 110.

The first solid-state laser device 200 includes the semiconductor laser system 101, a solid-state amplifier 202, a solid-state amplifier 203, and a solid-state amplifier 204.

The solid-state amplifier 202 and the solid-state amplifier 203 may each be a semiconductor optical amplifier (SOA). The SOA is, for example, a multiple quantum well structure of InP/InGaAsP.

The solid-state amplifier 202 cuts out a portion of the CW laser beam output from the semiconductor laser system 101 in a pulse shape and amplifies it to attain a first pulse laser beam PL1 by a trigger 3 signal sent from the solid-state seeder control processor 160. The solid-state amplifier 202 is an example of a “first amplifier”in the present disclosure.

The solid-state amplifier 203 further cuts out and amplifies a portion of the first pulse laser beam PL1 to attain a second pulse laser beam PL2 by a trigger 1 signal sent from the solid-state seeder control processor 160. The trigger 1 signal is an example of a “first trigger signal” in the present disclosure. The solid-state amplifier 203 is an example of a “second amplifier” in the present disclosure.

The solid-state amplifier 204 is, for example, an optical fiber amplifier doped with Yb of rare earth ions. The solid-state amplifier 204 amplifies power of the second pulse laser beam PL2 based on a gain signal sent from the solid-state seeder control processor 160 to attain a fifth pulse laser beam PL5. In the following, an amplification gain of the solid-state amplifier 204 is referred to as Gain. The solid-state amplifier 204 is an example of a “fourth amplifier” in the present disclosure.

The second solid-state laser device 210 does not include the dichroic mirror 116 as compared to the second solid-state laser device 110. The solid-state amplifier 113 cuts out the CW laser beam output from the semiconductor laser system 111 in the pulse shape and amplifies it to attain a third pulse laser beam PL3 by a trigger 2 signal sent from the solid-state seeder control processor 160. The trigger 2 signal is an example of a “second trigger signal” in the present disclosure. The solid-state amplifier 113 is an example of a “third amplifier”in the present disclosure.

The LBO crystal 114 converts the third pulse laser beam PL3 having the wavelength of about 1030 nm from the solid-state amplifier 113, which is modulated and cut out in the pulse shape, to the pulse laser beam having the wavelength of about 515 nm. The CLBO crystal 115 converts the pulse laser beam having the wavelength of about 515 nm converted by the LBO crystal 114 to a sixth pulse laser beam PL6 having the wavelength of about 257.6 nm.

The fifth pulse laser beam PL5 having the wavelength of about 1554 nm output from the first solid-state laser device 200 and the sixth pulse laser beam PL6 having the wavelength of about 257.6 nm output from the second solid-state laser device 210 are subjected to sum-frequency mixing by the CLBO crystal 141 of the wavelength conversion system 140, and are wavelength-converted to the pulse laser beam having the wavelength of about 220.9 nm. Further, the pulse laser beam having the wavelength of about 220.9 nm is converted to a fourth pulse laser beam PL4 having the wavelength of about 193.4 nm by the CLBO crystal 142, and is output from the solid-state seeder 21.

The wavelength conversion system 140 may perform sum-frequency mixing using the second pulse laser beam PL2, which is output of the solid-state amplifier 203 of the first solid-state laser device 200, instead of the fifth pulse laser beam PL5.

Further, the wavelength conversion system 140 may be formed of an optical crystal that performs sum-frequency mixing at a wavelength different from the above example, the pulse laser beam from the first solid-state laser device 200 and the pulse laser beam from the second solid-state laser device 210 may be subjected to sum-frequency mixing and wavelength-converted to be output of the solid-state seeder 21. In this case, the pulse laser beam from the first solid-state laser device 200 and the pulse laser beam from the second solid-state laser device 210 may be the ones outputting the wavelength different from the above example, respectively.

That is, the wavelength conversion system 140 may perform sum-frequency mixing, for wavelength-conversion, of the second pulse laser beam PL2 or the fifth pulse laser beam PL5 from the first solid-state laser device 200 and the third pulse laser beam PL3 or the sixth pulse laser beam PL6 from the second solid-state laser device 210.

The laser control processor 50 generates the trigger A signal and the trigger B signal in synchronization with the light emission trigger signal sent from the exposure control processor 61 of the exposure apparatus 60 illustrated in FIG. 6. The solid-state seeder control processor 160 generates the trigger 1 signal, the trigger 2 signal, and the trigger 3 signal in synchronization with the trigger B signal. Therefore, the trigger 1 signal, the trigger 2 signal, and the trigger 3 signal are synchronized with the light emission trigger signal.

### 2.2 Operation

### 2.2.1 Time of Laser Operation Execution

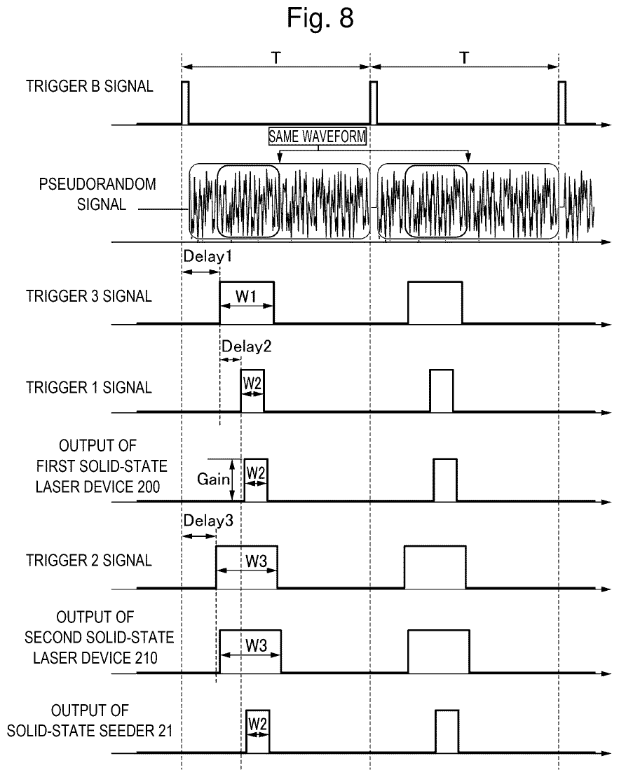

FIG. 8 illustrates a timing chart at the time of laser operation execution when timing adjustment to be described later in Embodiment 1 is completed and the solid-state seeder 21 is operated.

The solid-state seeder control processor 160 receives the spectral linewidth control signal, the temperature value and the current value for the semiconductor laser system 101 and the semiconductor laser system 111, and the trigger B signal from the laser control processor 50, and executes following control operations (1) to (6).
(1) The solid-state seeder control processor 160 controls the oscillation wavelength and the output of CW light of the semiconductor laser system 101 and the semiconductor laser system 111 based on the received temperature value and current value.
(2) The solid-state seeder control processor 160 operates the pseudorandom signal generator 150 after resetting the shift register 151 of the pseudorandom signal generator 150 based on the timing of the trigger B signal.
(3) The solid-state seeder control processor 160 generates the trigger 3 signal having a pulse width W1 by adding Delay1 which is delay time based on the timing of the trigger B signal as control of the first solid-state laser device 200. The solid-state amplifier 202 amplifies the CW light having the wavelength of about 1554 nm output from the semiconductor laser system 101, and converts it to the first pulse laser beam PL1. The pulse width of the first pulse laser beam PL1 is about W1.
(4) The solid-state seeder control processor 160 generates the trigger 1 signal having a pulse width W2 by adding Delay2 which is the delay time further to the timing of the trigger 3 signal. The solid-state amplifier 203 further amplifies the first pulse laser beam PL1 output from the solid-state amplifier 202 and cuts it out by a time width in which the pulse width is about W2 to generate the second pulse laser beam PL2. The solid-state seeder control processor 160 may add the delay time of Delay1+Delay2 based on the trigger B signal to generate the trigger 1 signal.
(5) The second pulse laser beam PL2 output by the solid-state amplifier 203 is further amplified in power by the solid-state amplifier 204 to be the fifth pulse laser beam PL5. The solid-state seeder control processor 160 controls Gain of the solid-state amplifier 204 to adjust the power of the fifth pulse laser beam PL5, which is the output of the first solid-state laser device 200.
(6) Meanwhile, the solid-state seeder control processor 160 generates the trigger 2 signal having a pulse width W3 by adding Delay3 which is the delay time based on the timing of the trigger B signal as the control of the second solid-state laser device 210. The solid-state amplifier 113 amplifies the CW light having the wavelength of about 1030 nm output from the semiconductor laser system 111 and modulated by the optical phase modulator 112 and cuts it out in the pulse shape to attain the third pulse laser beam PL3. The pulse width of the third pulse laser beam PL3 is about W3.

The third pulse laser beam PL3 is wavelength-converted to the pulse laser beam having the wavelength of about 257.6 nm via the LBO crystal 114 and the CLBO crystal 115 to be the sixth pulse laser beam PL6 as output light of the second solid-state laser device 210.

Thereafter, the solid-state seeder control processor 160 adjusts the rotation stage 143 and the rotation stage 144 of the wavelength conversion system 140 and converts the fifth pulse laser beam PL5 which is the output of the first solid-state laser device 200 and the sixth pulse laser beam PL6 which is the output of the second solid-state laser device 210 to the fourth pulse laser beam PL4 having the wavelength of about 193.4 nm through two-stage sum-frequency mixing (the CLBO crystal 141 and the CLBO crystal 142).

As described above, the fourth pulse laser beam PL4 which is the output of the solid-state seeder 21 is generated by overlap of the timings of the fifth pulse laser beam PL5 and the sixth pulse laser beam PL6.

Therefore, the fourth pulse laser beam PL4 is generated based on the overlap of the trigger 1 signal and the trigger 2 signal.

In the operation at the time of the laser operation execution, similarly to the laser apparatus 10, the laser control processor 50 receives the target center wavelength, the target linewidth, the target pulse energy, and the light emission trigger signal from the exposure control processor 61 of the exposure apparatus 60, sends the trigger A signal and the charging voltage value to the excimer amplifier 30 and sends the trigger B signal, the linewidth control signal, the temperature value, and the current value to the solid-state seeder 21 to operate the laser apparatus 11, and controls the pulse laser beam.

With the configuration and the operation, since the pseudorandom signal of the same pattern is generated in synchronization with the trigger 2 signal synchronized with the timing of the light emission trigger signal and is superimposed onto the optical phase modulator 112, the modulation signal of the same waveform for each pulse is superimposed onto the optical phase modulator 112, and the spectrum of the signal to be superimposed is also the same for each pulse. Therefore, since the laser beam output from the optical phase modulator 112 is modulated the same for each pulse, the spectrum becomes the same for each pulse, the spectral linewidth also becomes the same for each pulse and becomes stable.

Further, with the configuration and the operation, the laser apparatus 11 can output the laser beam of a wide unimodal spectrum with an enlarged adjustment range of the spectral linewidth as compared to the laser apparatus 10.

### 2.2.2 Time of Adjustment

A spectral linewidth timing adjusting method for outputting the wide unimodal spectrum from the solid-state seeder 21 will be described.

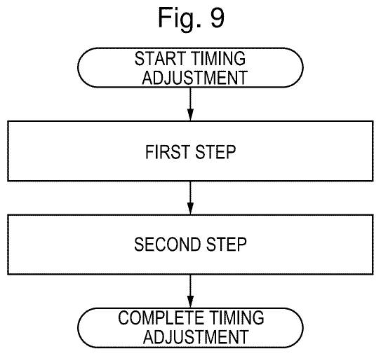

FIG. 9 illustrates a flowchart at the time of the timing adjustment. As illustrated in FIG. 9, the timing adjustment includes a first step and a second step executed following the first step.

### 2.2.2.1 First Step

In the first step, at least one of the timing of the trigger 1 signal and the timing of the trigger 2 signal is adjusted, and the spectrum of the fourth pulse laser beam PL4 is adjusted to a first spectrum in a non-Gaussian shape. Here, in the first step, by changing a start timing of the trigger 1 signal and measuring the spectrum of the fourth pulse laser beam PL4, the start timing of the trigger 1 signal at which the spectrum of the fourth pulse laser beam PL4 becomes the first spectrum in the non-Gaussian shape is searched.

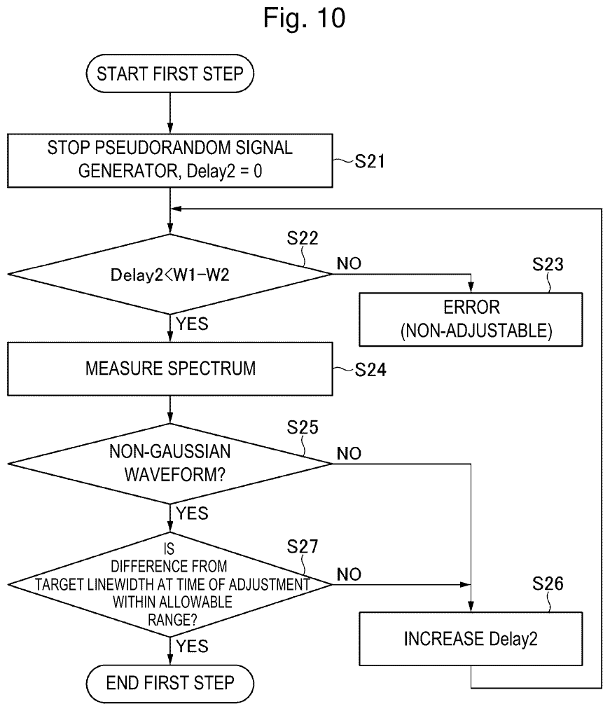

FIG. 10 illustrates a flowchart of the first step. In step S21, the solid-state seeder control processor 160 stops the pseudorandom signal generator 150. In addition, the solid-state seeder control processor 160 sets Delay2 to 0.

In step S22, the solid-state seeder control processor 160 determines whether Delay2 is smaller than (W1−W2). W1 is the width of the trigger 3 signal, and W2 is the width of the trigger 1 signal. If a determination result in step S22 is NO determination, that is, if Delay2 is not smaller than (W1−W2), the solid-state seeder control processor 160 proceeds to step S23.

In step S23, the solid-state seeder control processor 160 determines that it is an error (non-adjustable) and ends processing of the timing adjustment.

On the other hand, if the determination result in step S22 is YES determination, that is, if Delay 2 is smaller than (W1−W2), the solid-state seeder control processor 160 proceeds to step S24.

In step S24, the solid-state seeder control processor 160 measures the spectrum of the fourth pulse laser beam PL4. The spectrum of the fourth pulse laser beam PL4 may be measured by the spectrum monitor 43. In this case, the spectrum monitor 43 measures the spectrum of the light obtained by amplifying the fourth pulse laser beam PL4 by the excimer amplifier 30. Alternatively, a beam splitter may be installed between the solid-state seeder 21 and the excimer amplifier 30 to monitor the spectrum of the fourth pulse laser beam PL4.

In step S25, the solid-state seeder control processor 160 determines whether the spectrum of the fourth pulse laser beam PL4 is a non-Gaussian waveform which is a waveform in the non-Gaussian shape.

If a determination result in step S25 is NO determination, that is, if the spectrum is not the non-Gaussian waveform, the solid-state seeder control processor 160 proceeds to step S26. In step S26, the solid-state seeder control processor 160 adds a fixed value to Delay2 and returns to step S22.

On the other hand, if the determination result in step S25 is YES determination, that is, if the spectrum is the non-Gaussian waveform, the solid-state seeder control processor 160 proceeds to step S27. In step S27, the solid-state seeder control processor 160 determines whether a difference between the spectral linewidth of the fourth pulse laser beam PL4 and the predetermined target linewidth at the time of adjustment is within an allowable range.

If a determination result in step S27 is NO determination, that is, if the difference from the target linewidth at the time of the adjustment is not within the allowable range, the solid-state seeder control processor 160 proceeds to step S26.

On the other hand, if the determination result in step S27 is YES determination, that is, if the difference from the target linewidth at the time of the adjustment is within the allowable range, the solid-state seeder control processor 160 ends the processing of the present flowchart and determines a value of Delay2. The most appropriate Delay2 may be selected by measuring the spectrum of the fourth pulse laser beam PL4 for all Delay2.

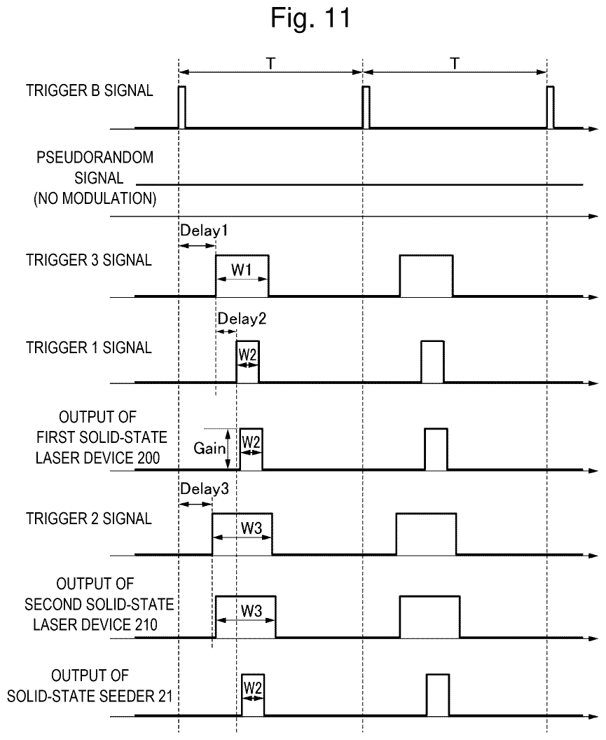

FIG. 11 illustrates a timing chart in the first step. As illustrated in FIG. 10 and FIG. 11, in the first step, the solid-state seeder control processor 160 stops the pseudorandom signal generator 150 and changes Delay2 in a state of not applying optical phase modulation of the second solid-state laser device 210 to adjust the fourth pulse laser beam PL4 to the first spectrum having the wider spectral linewidth than a Gaussian shape.

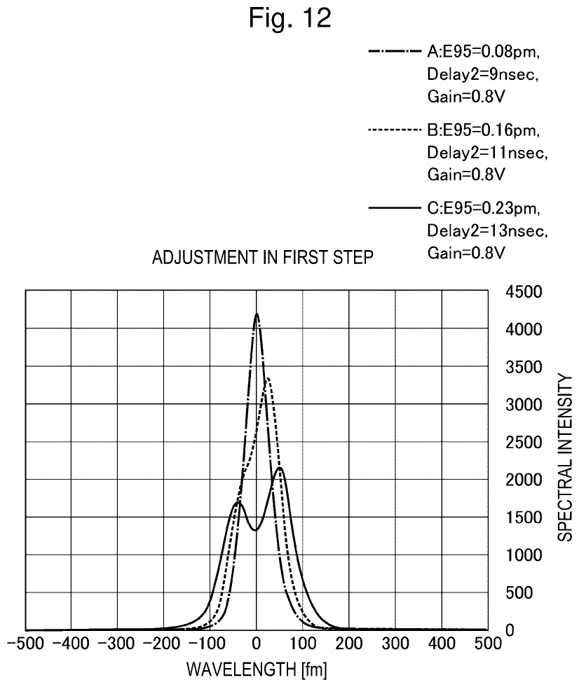

FIG. 12 illustrates the spectrum of the fourth pulse laser beam PL4 in the adjustment in the first step. For waveforms A, B, and C illustrated in FIG. 12, Delay2 is 9 nsec, 11 nsec, and 13 nsec respectively, Gain is 0.8 V respectively, and the E95 width is 0.08 pm, 0.16 pm, and 0.23 pm respectively. When Delay2 is changed, as illustrated in FIG. 12, the spectrum of the fourth pulse laser beam PL4 changes from a narrow Gaussian shape (unimodal) to the spectrum having the spectral linewidth wider than the Gaussian shape, and further changes to a multimodal spectrum.

In the first step, Delay2 to be a wide spectrum such as the waveforms B and C illustrated in FIG. 12 is selected. In the first step, when Delay2 to be a narrow unimodal spectrum such as the waveform A illustrated in FIG. 12 is selected, it is difficult to obtain a wide spectrum when phase modulation by the pseudorandom signal is applied in the second step.

Note that whether the fourth pulse laser beam PL4 in step S25 in FIG. 10 is the non-Gaussian waveform is determined by fitting the measured spectrum with the Gaussian waveform by a least squares method and using a size of a determination coefficient R2. For example, if R2 is smaller than 0.9, it is determined to be the non-Gaussian waveform.

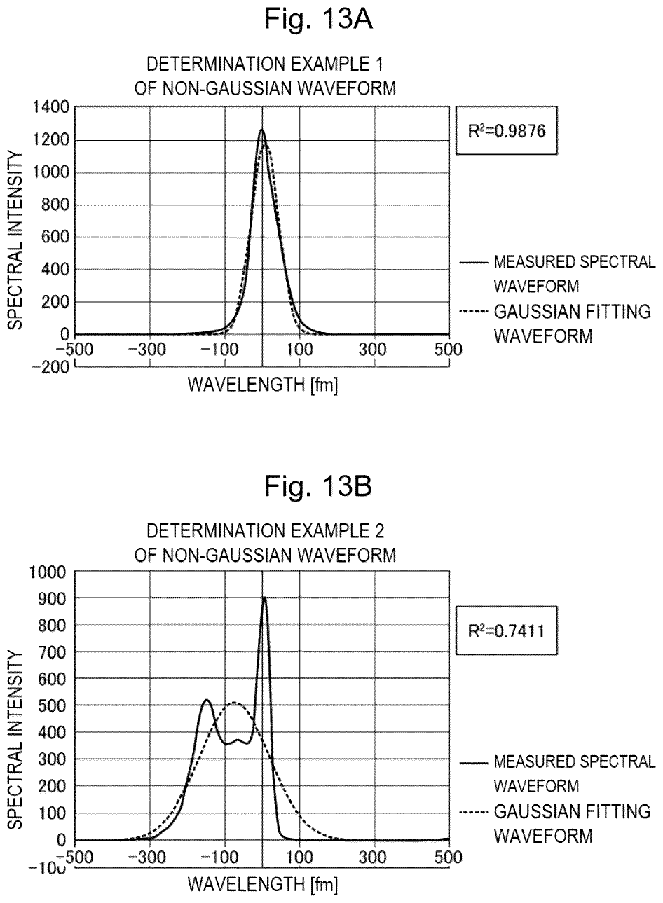

FIGS. 13A and 13B illustrate determination examples of the non-Gaussian waveform. FIGS. 13A and 13B each include graphs indicating the measured spectra and Gaussian fitting waveforms. The spectrum in FIG. 13A satisfies R²=0.9876 and does not satisfy R²<0.9. Therefore, the spectrum in FIG. 13A is determined to be the Gaussian waveform.

On the other hand, the spectrum in FIG. 13B satisfies R²=0.7411 and satisfies R²<0.9. Therefore, the spectrum in FIG. 13B is determined to be the non-Gaussian waveform.

In the first step, the spectrum is adjusted by changing Delay2 within a range of 0 to (W1−W2). When Delay2 is negative or is larger than (W1−W2), a time width of the fifth pulse laser beam PL5 which is the output of the first solid-state laser device 200 is shorter than W2. Further, when Delay2 is shifted such that there is no temporal overlap of the trigger 3 signal and the trigger 1 signal, the fifth pulse laser beam PL5 and even the fourth pulse laser beam PL4 which is the output of the solid-state seeder 21 are eliminated so that attention needs to be paid.

Similarly, attention needs to be paid to setting Delay3 and W3 so as to generate the overlap of the trigger 1 signal and the trigger 2 signal.

By adjusting the timing based on the above, the fourth pulse laser beam PL4 is output from the solid-state seeder 21 according to the timing of the trigger 1 signal.

A length of Delay1+Delay2 that determines the timing of the trigger 1 signal needs to be adjusted in accordance with an optical amplification timing of the excimer amplifier 30. Therefore, in the first step, after adjusting Delay2, the adjustment may be executed such that the output pulse laser beam of the solid-state seeder 21 overlaps with the amplification timing of the excimer amplifier 30 by changing the timing of the trigger 1 signal by Delay1. At that time, Delay3 may be also changed in accordance with change of Delay1 so that a relative timing difference between the trigger 3 signal and the trigger 2 signal does not change.

Alternatively, in the first step, Delay1 and Delay3 may be fixed, and after adjusting Delay2, the adjustment may be executed so that a time difference between the trigger A signal and the trigger B signal becomes an appropriate amplification timing.

### 2.2.2.2 Second Step

In the second step, by causing the pseudorandom signal generator 150 to generate the modulation signal of the same pattern synchronized with the light emission trigger signal and supplying the modulation signal of the same pattern to the optical phase modulator 112, the wavelength of the second continuous light is modulated within the time corresponding to one pulse of the third pulse laser beam PL3 and the spectrum of the fourth pulse laser beam PL4 is adjusted to a second spectrum having the spectral linewidth wider than the first spectrum. Here, in the second step, the pseudorandom signal generator 150 is operated, the spectrum of the fourth pulse laser beam PL4 is observed, and a search is performed by changing the initial value of the shift register 151 of the pseudorandom signal generator 150 so that the spectrum of the fourth pulse laser beam PL4 becomes the second spectrum which is unimodal and wide.

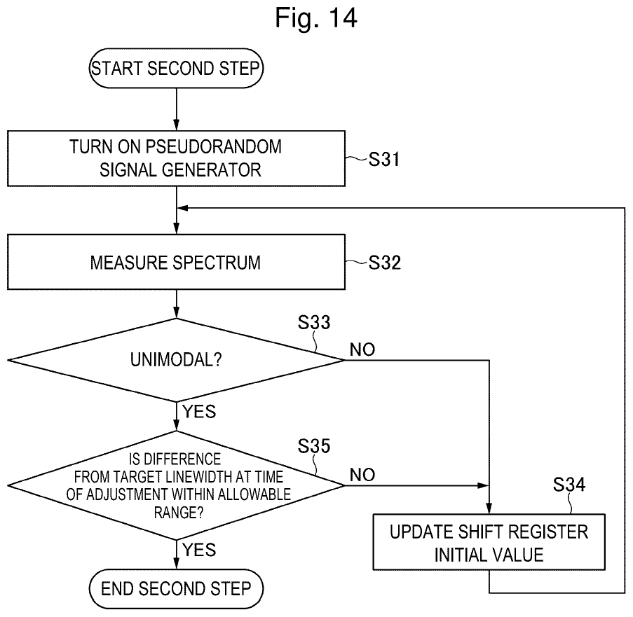

FIG. 14 illustrates a flowchart of the second step. In step S31, the solid-state seeder control processor 160 operates the pseudorandom signal generator 150.

In step S32, the solid-state seeder control processor 160 measures the spectrum of the fourth pulse laser beam PL4.

In step S33, the solid-state seeder control processor 160 determines whether the spectrum of the fourth pulse laser beam PL4 is unimodal.

If a determination result in step S33 is NO determination, that is, if the spectrum is not unimodal, the solid-state seeder control processor 160 proceeds to step S34. In step S34, the solid-state seeder control processor 160 updates the initial value of the shift register 151 and returns to step S32.

On the other hand, if the determination result in step S33 is YES determination, that is, if the spectrum is unimodal, the solid-state seeder control processor 160 proceeds to step S35. In step S35, the solid-state seeder control processor 160 determines whether a difference between the spectral linewidth of the fourth pulse laser beam PL4 and the unimodal target linewidth is within an allowable range.

If a determination result in step S35 is NO determination, that is, if the difference from the unimodal target linewidth is not within the allowable range, the solid-state seeder control processor 160 proceeds to step S34.

On the other hand, if the determination result in step S35 is YES determination, that is, if the difference from the unimodal target linewidth is within the allowable range, the solid-state seeder control processor 160 ends the processing of the present flowchart and determines the initial value of the shift register 151. The most appropriate initial value may be selected by executing evaluation of the spectrum for all the initial values of the shift register 151.

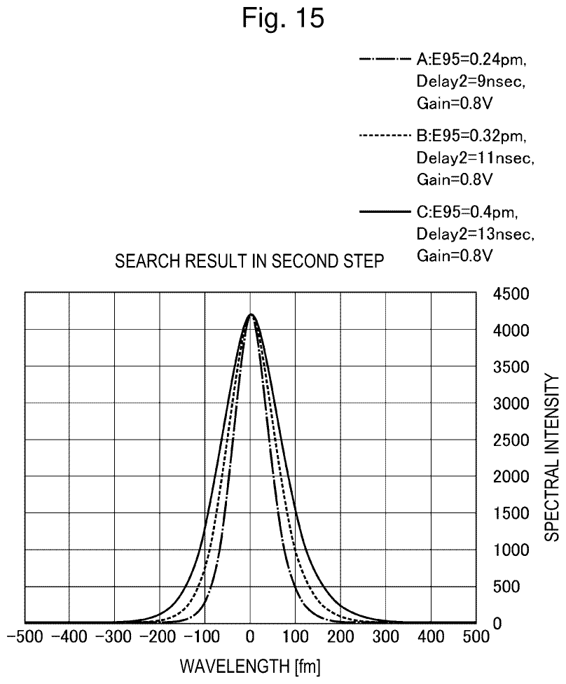

FIG. 15 illustrates the spectrum of the fourth pulse laser beam PL4 after the search in the second step. Waveforms A, B, and C in FIG. 15 are the spectrums of the fourth pulse laser beam PL4 after the initial value of the shift register 151 is determined for the waveforms A, B, and C in FIG. 12, respectively. For the waveforms A, B, and C illustrated in FIG. 15, the E95 width is 0.24 pm, 0.32 pm, and 0.4 pm respectively. When a wide multimodal spectrum such as the waveform C in FIG. 12 is selected in the adjustment of Delay2, a wide unimodal spectrum such as the waveform C in FIG. 15 is obtained.

In contrast, when a narrow unimodal spectrum such as the waveform A in FIG. 12 is selected, a narrow unimodal spectrum such as the waveform A in FIG. 15 is obtained.

### 2.3 Effect and Advantage

In the laser apparatus 10 according to the comparative example, the output pulse laser beam of the solid-state seeder 20 in a state where the pseudorandom signal generator 150 is stopped and the optical phase modulation of the second solid-state laser device 110 is not applied corresponds to the waveform A in FIG. 12. It is because that, since a goal is to eventually make the output pulse laser beam of the solid-state seeder 20 unimodal (Gaussian shape), if the spectrum is made unimodal (Gaussian shape) even in the state where the phase modulation is not applied, it becomes easy to operate the pseudorandom signal generator 150 thereafter and to perform a search by changing the initial value of the shift register 151 of the pseudorandom signal generator 150 so that the spectrum has a unimodal shape (the waveform A in FIG. 15). Therefore, the spectrum of the pulse laser beam output from the solid-state amplifier 102 of the laser apparatus 10 according to the comparative example is designed and manufactured so as to be the Gaussian shape (the waveform A in FIG. 12). Further, since the solid-state amplifier 102 uses the pulse laser beam having the wavelength of 1030 nm that cannot be wavelength-converted in the LBO crystal as the pump light, the adjustment of the amplification timing of the solid-state amplifier 102 which corresponds to the adjustment of Delay2 in Embodiment 1 is difficult.

On the other hand, the laser apparatus 11 according to Embodiment 1 adjusts Delay 2 in the state where the pseudorandom signal generator 150 is stopped and the optical phase modulation of the second solid-state laser device 210 is not applied, as the first step. Thus, the spectrum having the spectral linewidth that is not the Gaussian shape and is wider than the Gaussian shape, such as the waveform B or the waveform C in FIG. 12, is once attained. Thereafter, as the second step, the laser apparatus 11 performs a search by changing the initial value of the shift register 151 of the pseudorandom signal generator 150 in the state where the optical phase modulation is applied. Thus, it is possible to shape the spectrum to obtain the wide and unimodal spectrum such as the waveform B or the waveform C in FIG. 15. In particular, by once performing the adjustment to the multimodal spectrum such as the waveform C in FIG. 12, it is possible to eventually obtain the wider spectrum such as the waveform C in FIG. 15.

### 3. Embodiment 2

### 3.1 Configuration

A configuration of the laser apparatus according to Embodiment 2 is the same as the configuration of the laser apparatus according to Embodiment 1. The laser apparatus 11 according to Embodiment 2 differs from the laser apparatus 11 according to Embodiment 1 in contents of the control executed by the solid-state seeder control processor 160.

### 3.2 Operation

In the first step of Embodiment 2, at least one of the timing of the trigger 1 signal and the timing of the trigger 2 signal is adjusted, Gain of the solid-state amplifier 204 is also adjusted, and the spectrum of the fourth pulse laser beam PL4 is adjusted to the first spectrum in the non-Gaussian shape. Here, in addition to the adjustment of Delay2, Gain is further adjusted to obtain the wide unimodal spectrum. The second step of Embodiment 2 is the same as that of Embodiment 1.

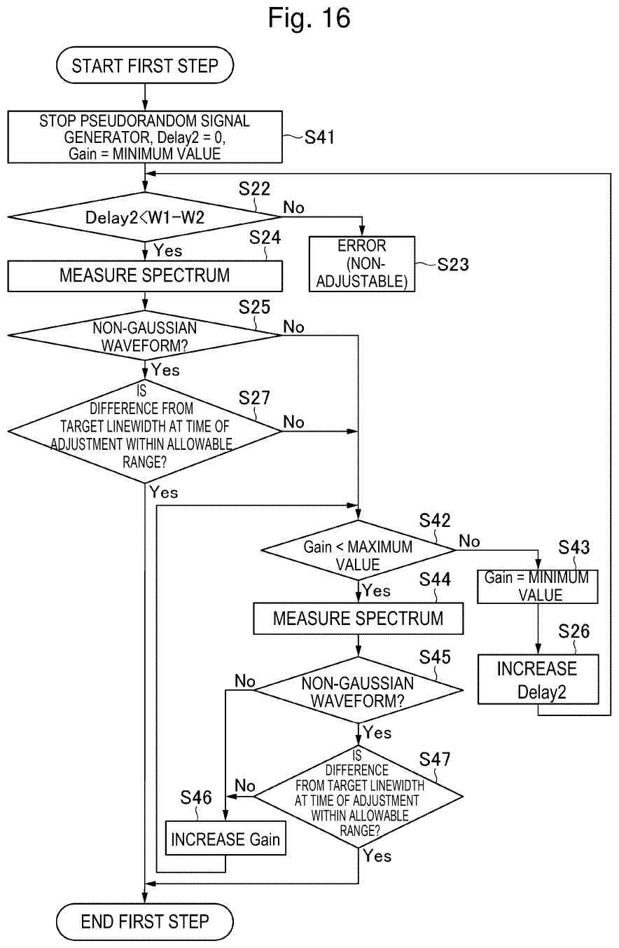

FIG. 16 illustrates a flowchart of the first step of Embodiment 2. In step S41, the solid-state seeder control processor 160 stops the pseudorandom signal generator 150. In addition, the solid-state seeder control processor 160 sets Delay2 to 0 and Gain to a minimum value.

The processing of steps S22 to S25 and step S27 is the same as that in FIG. 10. If the determination result in step S25 is YES determination and the determination result in step S27 is also YES determination, the solid-state seeder control processor 160 ends the processing of the present flowchart and determines values of Delay2 and Gain.

On the other hand, if the determination result in step S25 is NO determination or the determination result in step S27 is NO determination, the solid-state seeder control processor 160 proceeds to step S42. In step S42, the solid-state seeder control processor 160 determines whether Gain is smaller than a maximum value.

If a determination result in step S42 is NO determination, that is, if Gain is not smaller than the maximum value, the solid-state seeder control processor 160 proceeds to step S43. In step S43, the solid-state seeder control processor 160 sets Gain to the minimum value. Thereafter, in step S26, the solid-state seeder control processor 160 adds a fixed value to Delay2 and returns to step S22.

On the other hand, if the determination result in step S42 is YES determination, that is, if Gain is smaller than the maximum value, the solid-state seeder control processor 160 proceeds to step S44. In step S44, the solid-state seeder control processor 160 measures the spectrum of the fourth pulse laser beam PL4.

In step S45, the solid-state seeder control processor 160 determines whether the spectrum of the fourth pulse laser beam PL4 is the non-Gaussian waveform. This determination may be made similarly to step S25.

If a determination result in step S45 is NO determination, that is, if the spectrum is not the non-Gaussian waveform, the solid-state seeder control processor 160 proceeds to step S46. In step S46, the solid-state seeder control processor 160 increments Gain by a fixed amount and returns to step S42.

On the other hand, if the determination result in step S45 is YES determination, that is, if the spectrum is the non-Gaussian waveform, the solid-state seeder control processor 160 proceeds to step S47. In step S47, the solid-state seeder control processor 160 determines whether the difference between the spectral linewidth of the fourth pulse laser beam PL4 and the target linewidth at the time of the adjustment is within an allowable range.

If a determination result in step S47 is NO determination, that is, if the difference from the target linewidth at the time of the adjustment is not within the allowable range, the solid-state seeder control processor 160 proceeds to step S46. On the other hand, if the determination result in step S47 is YES determination, that is, if the difference from the target linewidth at the time of the adjustment is within the allowable range, the solid-state seeder control processor 160 ends the processing of the present flowchart and determines the values of Delay2 and Gain.

In the first step of Embodiment 2, if a desired multimodal spectrum is obtained only by adjusting Delay2, the adjustment of Gain may not be executed as in Embodiment 1. On the other hand, if the desired multimodal spectrum cannot be obtained only by adjusting Delay2, Gain is adjusted. It is also possible to adjust Gain first and adjust Delay2 when the desired multimodal spectral cannot be obtained.

The spectrums in all combinations of Delay2 and Gain may be examined to select the best one.

### 3.3 Effect and Advantage

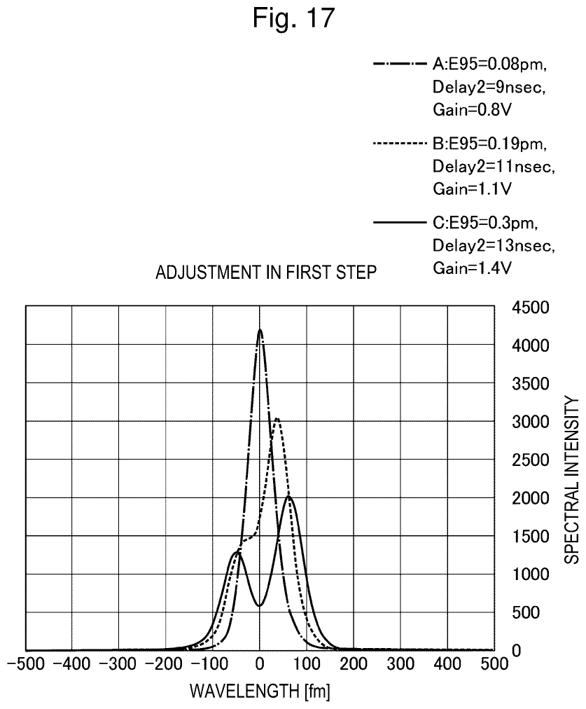

FIG. 17 illustrates the spectrum of the fourth pulse laser beam PL4 in the adjustment in the first step. For waveforms A, B, and C illustrated in FIG. 17, Delay2 is 9 nsec, 11 nsec, and 13 nsec respectively, Gain is 0.8 V, 1.1 V, and 1.4V respectively, and the E95 width is 0.08 pm, 0.19 pm, and 0.3 pm respectively.

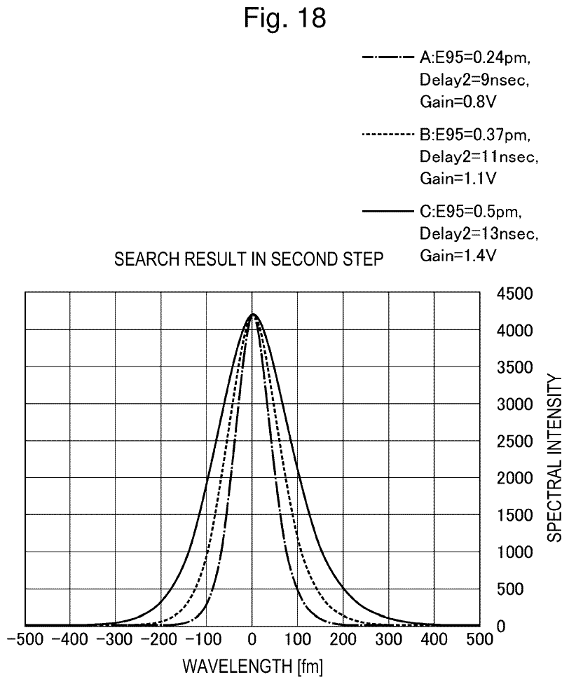

FIG. 18 illustrates the spectrum of the fourth pulse laser beam PL4 after the search in the second step. Waveforms A, B, and C in FIG. 18 are the spectrums of the fourth pulse laser beam PL4 after the initial value of the shift register 151 is determined for the waveforms A, B, and C in FIG. 17, respectively. For the waveforms A, B, and C illustrated in FIG. 18, the E95 width is 0.24 pm, 0.37 pm, and 0.5 pm, respectively.

As illustrated in FIG. 17 and FIG. 18, a wider spectrum is obtained by combining the adjustment of Delay2 and the adjustment of Gain.

### 4. Embodiment 3

### 4.1 Configuration

A configuration of the laser apparatus according to Embodiment 3 is the same as the configuration of the laser apparatus according to Embodiment 1. The laser apparatus 11 according to Embodiment 3 differs from the laser apparatus 11 according to Embodiment 1 in contents of the control executed by the solid-state seeder control processor 160.

### 4.2 Operation

In the first step of Embodiment 3, by changing Delay3 which is a start timing of the trigger 2 signal and measuring the spectrum of the fourth pulse laser beam PL4, the start timing of the trigger 2 signal at which the spectrum of the fourth pulse laser beam PL4 becomes the first spectrum in the non-Gaussian shape is searched. The second step of Embodiment 3 is the same as that of Embodiment 1.

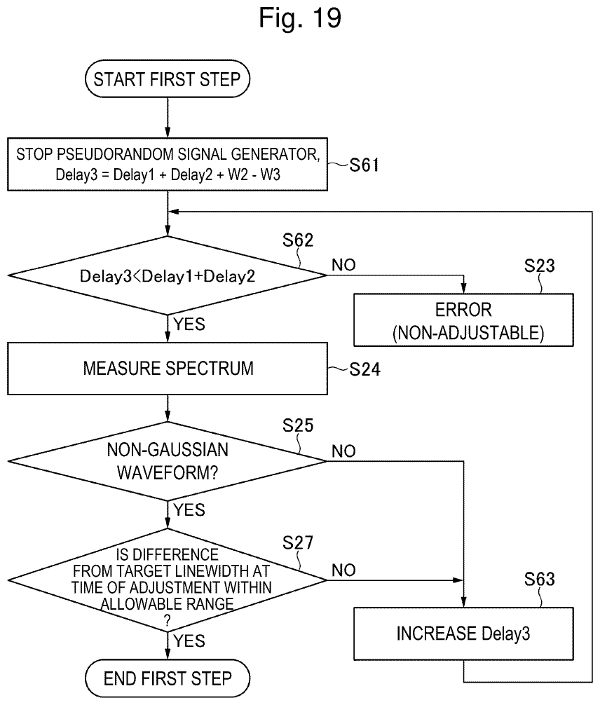

FIG. 19 illustrates a flowchart of the first step of Embodiment 3. In step S61, the solid-state seeder control processor 160 stops the pseudorandom signal generator 150. In addition, the solid-state seeder control processor 160 sets Delay3 to (Delay1+Delay2+W2−W3).

In step S62, the solid-state seeder control processor 160 determines whether Delay3 is smaller than (Delay1+Delay2). If a determination result in step S62 is NO determination, that is, if Delay3 is not smaller than (Delay1+Delay2), the solid-state seeder control processor 160 proceeds to step S23. The processing of step S23 is the same as that of step S23 in FIG. 10.

On the other hand, if the determination result in step S62 is YES determination, that is, if Delay3 is smaller than (Delay1+Delay2), the solid-state seeder control processor 160 proceeds to step S24.

The processing of steps S24, S25, and S27 is the same as that of steps S24, S25, and S27 in FIG. 10. If the determination result in step S25 is YES determination and the determination result in step S27 is also YES determination, the solid-state seeder control processor 160 ends the processing of the present flowchart and determines a value of Delay3.

On the other hand, if the determination result in step S25 is NO determination or the determination result in step S27 is NO determination, the solid-state seeder control processor 160 proceeds to step S63. In step S63, the solid-state seeder control processor 160 adds a fixed value to Delay3 and returns to step S62.

Thus, a difference in a pulse cut-out timing between the first solid-state laser device 200 and the second solid-state laser device 210 is adjusted by adjusting Delay3, and the spectrum of the fourth pulse laser beam PL4 is adjusted to be wide and multimodal. The most appropriate Delay 3 may be selected by measuring the spectrum of the fourth pulse laser beam PL4 for all Delay3.

When Delay3 is to be adjusted, attention needs to be paid to setting Delay3 and W3 so as to generate the overlap of the trigger 1 signal and the trigger 2 signal. Specifically, Delay3 and W3 are set so as to satisfy Expression 1 below.
Delay1+Delay2+W2−W3<Delay3<Delay1+Delay2 . . . (Expression 1)

Further, the adjustment of Delay3 in the first step of Embodiment 3 may be executed in combination with the adjustment of Delay1 of Embodiment 1, may be executed in combination with the adjustment of Gain of Embodiment 2, or may be executed in combination with the adjustment of Delay1 and Gain of Embodiment 2.

### 4.3 Effect and Advantage

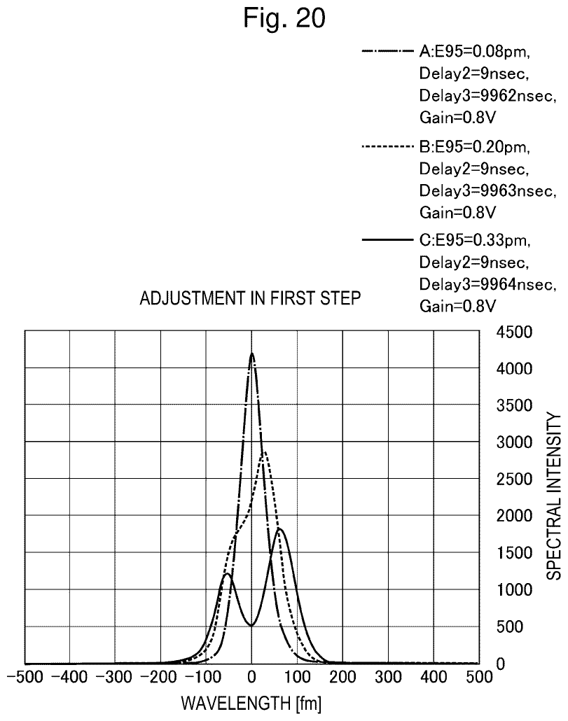

FIG. 20 illustrates the spectrum of the fourth pulse laser beam PL4 in the adjustment in the first step. For waveforms A, B, and C illustrated in FIG. 20, Delay2 is 9 nsec respectively, Delay3 is 9962 ns, 9963 ns, and 9964 ns respectively, Gain is 0.8 V respectively, and the E95 width is 0.08 pm, 0.20 pm, and 0.33 pm respectively.

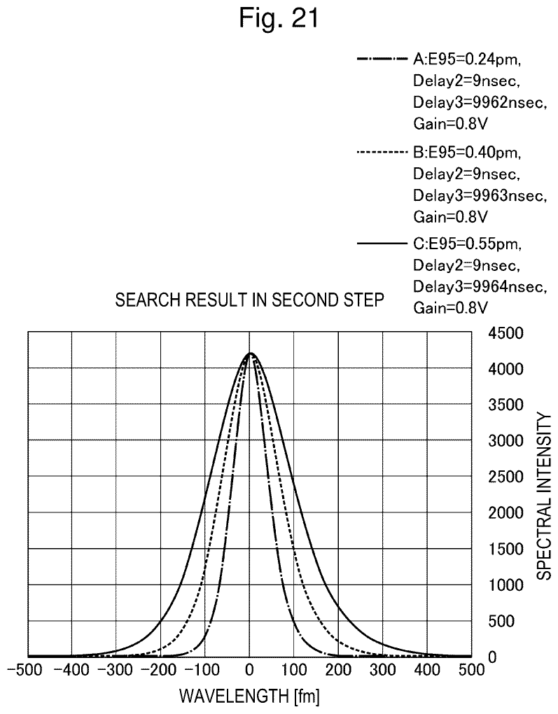

FIG. 21 illustrates the spectrum of the fourth pulse laser beam PL4 after the search in the second step.

Waveforms A, B, and C in FIG. 21 are the spectrums of the fourth pulse laser beam PL4 after the initial value of the shift register 151 is determined for the waveforms A, B, and C in FIG. 20, respectively. For the waveforms A, B, and C illustrated in FIG. 21, the E95 width is 0.24 pm, 0.40 pm, and 0.55 pm, respectively.

As illustrated in FIG. 20 and FIG. 21, a wider spectrum is obtained by adjusting Delay3.

The processor such as the laser control processor 50 and the exposure control processor 61 may be physically configured as hardware to execute the various kinds of processing included in the present disclosure. For example, the processor may be a computer including a memory that stores a control program defining the various kinds of processing and a processing device that executes the control program. The control program may be stored in one memory, or may be stored separately in a plurality of memories at physically separate locations, and the various kinds of processing may be defined by a combination of control programs stored in the memories. The processing device may be a general-purpose processing device such as a CPU or a special-purpose processing device such as a GPU.

Alternatively, the processor may be programmed as software to execute the various kinds of processing included in the present disclosure. For example, for the processor, functions to execute the various kinds of processing may be implemented in a dedicated device such as an ASIC or a programmable device such as a FPGA.

The various kinds of processing included in the present disclosure may be executed by one computer, one dedicated device, or one programmable device, or may be executed by cooperation of a plurality of computers, a plurality of dedicated devices, or a plurality of programmable devices at physically separate locations. The various kinds of processing may be executed by a combination including at least any two of: one or more computers, one or more dedicated devices, and one or more programmable devices.

### 5. Electronic Device Manufacturing Method

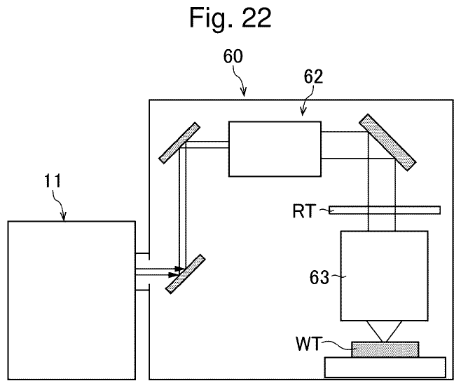

FIG. 22 schematically illustrates a configuration example of the exposure apparatus 60. The exposure apparatus 60 includes an illumination optical system 62 and a projection optical system 63. The laser apparatus 11 generates a laser beam, and outputs the laser beam to the exposure apparatus 60. The illumination optical system 62 illuminates a reticle pattern of an unillustrated reticle disposed on a reticle stage RT with the laser beam incoming from the laser apparatus 11. The projection optical system 63 performs reduced projection of the laser beam transmitted through the reticle, and forms an image on an unillustrated workpiece disposed on a workpiece table WT. The workpiece is a photosensitive substrate such as a semiconductor wafer on which photoresist is applied.

The exposure apparatus 60 synchronously translates the reticle stage RT and the workpiece table WT to expose the workpiece to the laser beam reflecting the reticle pattern. After the reticle pattern is transferred onto the semiconductor wafer by an exposure process as above, a semiconductor device can be manufactured through a plurality of processes. The semiconductor device is an example of an “electronic device” in the present disclosure.

### 6. Others

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined.

The terms used throughout the present specification and the appended claims should be interpreted as non-limiting terms unless clearly described. For example, terms such as “comprise”, “include”, “have”, and “contain” should not be interpreted to be exclusive of other structural elements. Further, indefinite articles “a/an” described in the present specification and the appended claims should be interpreted to mean “at least one” or “one or more.” Further, “at least one of A, B, and C” should be interpreted to mean any of A, B, C, A+B, A+C, B+C, and A+B+C as well as to include combinations of any thereof and any other than A, B, and C.

What is claimed is:

1. A spectral linewidth adjusting method for a pulse laser beam output by a laser apparatus, the laser apparatus including
a first semiconductor laser configured to output first continuous light,
a first amplifier configured to amplify a portion of the first continuous light in synchronization with a light emission trigger signal received from an external device and to convert the portion of the first continuous light to a first pulse laser beam,
a second amplifier configured to amplify a portion of the first pulse laser beam using a first trigger signal generated in synchronization with the light emission trigger signal and to convert the portion of the first pulse laser beam to a second pulse laser beam,
a second semiconductor laser configured to output second continuous light,
a third amplifier configured to amplify a portion of the second continuous light using a second trigger signal generated in synchronization with the light emission trigger signal and to convert the portion of the second continuous light to a third pulse laser beam,
an optical phase modulator disposed in an optical path of the second continuous light between the second semiconductor laser and the third amplifier,
a modulation signal generator configured to output a modulation signal to be supplied to the optical phase modulator, and
a wavelength conversion system configured to perform sum-frequency mixing of the second pulse laser beam and the third pulse laser beam for wavelength conversion and to output a fourth pulse laser beam,
the spectral linewidth adjusting method comprising:
a first step of adjusting at least one of a timing of the first trigger signal and a timing of the second trigger signal and adjusting a spectrum of the fourth pulse laser beam to a first spectrum in a non-Gaussian shape; and
a second step of modulating a wavelength of the second continuous light within time corresponding to one pulse of the third pulse laser beam and adjusting the spectrum of the fourth pulse laser beam to a second spectrum having a spectral linewidth wider than the first spectrum by causing the modulation signal generator to generate the modulation signal of a same pattern synchronized with the light emission trigger signal and supplying the modulation signal of the same pattern to the optical phase modulator.

2. The spectral linewidth adjusting method according to claim 1, further comprising
a fourth amplifier configured to amplify the second pulse laser beam and to convert the second pulse laser beam to a fifth pulse laser beam, wherein
the wavelength conversion system performs sum-frequency mixing of the fifth pulse laser beam and the third pulse laser beam for wavelength conversion and outputs the fourth pulse laser beam, and
in the first step, at least one of the timing of the first trigger signal and the timing of the second trigger signal is adjusted, an amplification gain of the fourth amplifier is adjusted, and the spectrum of the fourth pulse laser beam is adjusted to the first spectrum in the non-Gaussian shape.

3. The spectral linewidth adjusting method according to claim 1, wherein
the modulation signal is a pseudorandom signal.

4. The spectral linewidth adjusting method according to claim 3, wherein
the modulation signal generator includes a shift register.

5. The spectral linewidth adjusting method according to claim 4, wherein
the modulation signal generator includes an initial value setting circuit, and
in the second step, an initial value of the shift register is set such that the second spectrum becomes unimodal.

6. The spectral linewidth adjusting method according to claim 1, wherein
the first spectrum is multimodal and the second spectrum is unimodal.

7. The spectral linewidth adjusting method according to claim 1, further comprising
a wavelength conversion crystal configured to convert a wavelength of the third pulse laser beam to attain a sixth pulse laser beam, wherein
the wavelength conversion system performs sum-frequency mixing of the second pulse laser beam and the sixth pulse laser beam for wavelength conversion and outputs the fourth pulse laser beam.

8. The spectral linewidth adjusting method according to claim 1, wherein
a wavelength of the fourth pulse laser beam is 193 nm.

9. The spectral linewidth adjusting method according to claim 1, wherein
in the first step, the modulation signal by the modulation signal generator is not output.

10. The spectral linewidth adjusting method according to claim 1, wherein
in the first step, the timing of the first trigger signal is adjusted.

11. The spectral linewidth adjusting method according to claim 10, wherein
in the first step, by changing a start timing of the first trigger signal and measuring the spectrum of the fourth pulse laser beam, the start timing of the first trigger signal at which the spectrum of the fourth pulse laser beam becomes the first spectrum in the non-Gaussian shape is searched.

12. The spectral linewidth adjusting method according to claim 10, wherein
in the first step, the spectrum of the fourth pulse laser beam is measured for all start timings of the first trigger signal.

13. The spectral linewidth adjusting method according to claim 11, wherein
in the first step, the measured spectrum of the fourth pulse laser beam is fitted with a Gaussian waveform by a least squares method, and whether the spectrum of the fourth pulse laser beam is in the non-Gaussian shape is determined.

14. The spectral linewidth adjusting method according to claim 11, wherein
in the first step, among start timings of the first trigger signal at which the spectrum of the fourth pulse laser beam becomes the first spectrum in the non-Gaussian shape, a start timing of the first trigger signal at which a difference between a predetermined target linewidth and a spectral linewidth of the fourth pulse laser beam is within an allowable range is selected.

15. The spectral linewidth adjusting method according to claim 1, wherein
in the first step, the timing of the second trigger signal is adjusted.

16. The spectral linewidth adjusting method according to claim 15, wherein
in the first step, by changing a start timing of the second trigger signal and measuring the spectrum of the fourth pulse laser beam, the start timing of the second trigger signal at which the spectrum of the fourth pulse laser beam becomes the first spectrum in the non-Gaussian shape is searched.

17. The spectral linewidth adjusting method according to claim 16, wherein
in the first step, the spectrum of the fourth pulse laser beam is measured for all start timings of the second trigger signal.

18. The spectral linewidth adjusting method according to claim 16, wherein
in the first step, the measured spectrum of the fourth pulse laser beam is fitted with a Gaussian waveform by a least squares method, and whether the spectrum of the fourth pulse laser beam is in the non-Gaussian shape is determined.

19. The spectral linewidth adjusting method according to claim 16, wherein
in the first step, among start timings of the second trigger signal at which the spectrum of the fourth pulse laser beam becomes the first spectrum in the non-Gaussian shape, a start timing of the second trigger signal at which a difference between a predetermined target linewidth and a spectral linewidth of the fourth pulse laser beam is within an allowable range is selected.

20. An electronic device manufacturing method comprising:
generating a fourth pulse laser beam by a laser apparatus, the laser apparatus including
a first semiconductor laser configured to output first continuous light,
a first amplifier configured to amplify a portion of the first continuous light in synchronization with a light emission trigger signal received from an external device and to convert the portion of the first continuous light to a first pulse laser beam,
a second amplifier configured to amplify a portion of the first pulse laser beam using a first trigger signal generated in synchronization with the light emission trigger signal and to convert the portion of the first pulse laser beam to a second pulse laser beam,
a second semiconductor laser configured to output second continuous light,
a third amplifier configured to amplify a portion of the second continuous light using a second trigger signal generated in synchronization with the light emission trigger signal and to convert the portion of the second continuous light to a third pulse laser beam,
an optical phase modulator disposed in an optical path of the second continuous light between the second semiconductor laser and the third amplifier,
a modulation signal generator configured to output a modulation signal to be supplied to the optical phase modulator, and
a wavelength conversion system configured to perform sum-frequency mixing of the second pulse laser beam and the third pulse laser beam for wavelength conversion and to output the fourth pulse laser beam,
the laser apparatus adjusting at least one of a timing of the first trigger signal and a timing of the second trigger signal and adjusting a spectrum of the fourth pulse laser beam to a first spectrum in a non-Gaussian shape, and
the laser apparatus modulating a wavelength of the second continuous light within time corresponding to one pulse of the third pulse laser beam and adjusting the spectrum of the fourth pulse laser beam to a second spectrum having a spectral linewidth wider than the first spectrum by causing the modulation signal generator to generate the modulation signal of a same pattern synchronized with the light emission trigger signal and supplying the modulation signal of the same pattern to the optical phase modulator;
outputting the fourth pulse laser beam to an exposure apparatus; and
exposing a photosensitive substrate to the fourth pulse laser beam within the exposure apparatus to manufacture an electronic device.
